(19) United States
(12) Patent Application Publication
(10) Pub. No.: US 2013/0242520 A1
(43) Pub. Date: Sep. 19, 2013

(54) INSULATING SUBSTRATE, METAL-CLAD LAMINATE, PRINTED WIRING BOARD AND SEMICONDUCTOR DEVICE

(71) Applicant: Iji Onozuka, Tokyo (JP)

(72) Inventor: Iji Onozuka, Tokyo (JP)

(73) Assignee: SUMITOMO BAKELITE CO., LTD., Tokyo (JP)

(21) Appl. No.: 13/885,321

(22) PCT Filed: Nov. 15, 2011
(86) PCT No.: PCT/JP2011/076254

§ 371 Date: May 14, 2013

(30) Foreign Application Priority Data
Nov. 18, 2010 (JP) 2010-258172
Sep. 26, 2011 (JP) 2011-209540

(51) Int. Cl. H05K 1/03

(52) U.S. Cl. CPC H05K 1/038
USPC 361/783; 174/250; 428/213; 428/215

(57) ABSTRACT

The present invention provides: an insulating substrate or metal-clad laminate able to sufficiently reduce or prevent negative warping of a semiconductor device; a printed wiring board that uses the insulating substrate or metal-clad laminate; and a semiconductor device. The insulating substrate is composed of a cured product of a laminate including one or more fibrous base material layers and two or more resin layers, in which the outermost layers on both sides is the resin layers. At least one of the fibrous base material layers is shifted towards the first side or a second side on the opposite side thereof with respect to the reference position, namely the dividing position at which a total thickness of the insulating substrate is equally divided by the number of the fibrous base material layers and each divided region having the thickness is further equally divided by two. The fibrous base material layers are not shifted in different directions. It is possible to produce a printed wiring board by using, as a core substrate, a metal-clad laminate containing the insulating substrate. Also, it is possible to produce a semiconductor device by mounting a semiconductor element onto the printed wiring board.

### TECHNICAL FIELD

The present invention relates to an insulating substrate and a metal-clad laminate serving as core substrates for producing a printed wiring board, a printed wiring board that uses the insulating substrate or the metal-clad laminate, and a semiconductor device.

The present application claims priority based on Japanese Patent Application No. 2010-258172, filed in Japan on Nov. 18, 2010, and Japanese Patent Application No. 2011-209540, filed in Japan on Sep. 26, 2011, the contents of which are incorporated herein by reference.

### BACKGROUND ART

Semiconductor devices (semiconductor packages) used in electronic equipment are continuing to become increasingly compact, have higher density, and demonstrate increasingly sophisticated functions, and examples of package forms include package-on-package (POP), system-in-package (SIP) and flip chip ball grid arrays (FCBGA). Accompanying the increasingly compact sizes and high densities of these semiconductor devices, the semiconductor elements and printed wiring boards that compose these semiconductor devices are also being required to demonstrate higher levels of compact size and reduced thickness.

In general, printed wiring boards are composed by providing a conductor circuit layer, and more recently a built-up, multilayered conductor circuit layer in particular, on a core substrate, while semiconductor devices are composed by mounting and connecting semiconductor elements on the conductor circuit layer of the aforementioned printed wiring boards.

Reducing the thickness of the support in the form of the core substrate is an effective method for reducing the thickness of printed wiring boards. However, since the linear coefficient of expansion of the core substrate (normally about 8 ppm to 15 ppm) is larger than the linear coefficient of expansion of a semiconductor element (normally about 3 ppm to 4 ppm), and the linear coefficient of expansion of the conductor circuit layer (normally about 18 ppm) is still larger than the linear coefficient of expansion of the core substrate, stress is generated within the printed wiring board and semiconductor device due to the difference in linear coefficients of expansion of each of these portions. Consequently, when the thickness of the core substrate is reduced, stress generated by differences in linear coefficients of expansion of each portion surpasses the rigidity of the core substrate, resulting in the problem of increased susceptibility to warping.

Ina printed wiring board on which a semiconductor element has not yet been mounted, either positive warping (see FIG. 15A), in which the surface of the side on which a semiconductor element is mounted bends inward, or negative warping (see FIG. 15B), in which the surface of the side on which a semiconductor element is mounted bends outward, occurs according to the balance between stress generated by the conductor circuit layer provided on a first side of the core substrate and stress generated by the conductor circuit layer provided on a second side being the opposite side of the first side.

In contrast, the direction of warping in a semiconductor device in which a semiconductor element has been mounted on a printed wiring board is normally negative warping, in which the surface on the side on which the semiconductor element is mounted bends outward, since the linear coefficient of expansion and rigidity of the semiconductor element act predominantly. If negative warping of the semiconductor device is excessively large, there is increased susceptibility to the occurrence of problems such a defective connections due to a shift in the connecting position when the surface of the semiconductor device on the opposite side from the semiconductor element mounted side is secondarily connected to a motherboard, or decreased reliability due to the destruction of the wiring layer in the semiconductor element during hot-cold shock testing or the formation of cracks in solder bumps connecting the printed wiring board and semiconductor element.

As a proposal for solving the problem of warping of a semiconductor device (semiconductor package), Patent Document 1 describes a built-up wiring board, in which a built-up wiring layer, obtained by laminating at least one layer each of an interlayer insulating resin layer and a wiring layer, is formed on a surface A and a surface B of a core substrate, wherein the coefficient of thermal expansion in the planar direction of the interlayer insulating resin layer on the side of the surface A where a semiconductor element is mounted is greater than the coefficient of thermal expansion in the planar direction of the interlayer insulating resin layer on the side of the surface B mounted on a mounting substrate.

### PRIOR ART DOCUMENTS

### Patent Documents

Patent Document 1: Japanese Unexamined Patent Application, First Publication No. 2008-294387

### SUMMARY OF INVENTION

### Problems to be Solved by the Invention

However, the effect of reducing warping of a semiconductor device obtained according to the invention of Patent Document 1 is not necessarily adequate.

In addition, in a method that attempts to prevent warping by adjusting the coefficient of linear expansion of an interlayer insulating resin layer contained in a built-up layer of a printed wiring board (built-up wiring board) as in the invention of Patent Document 1, the number of wiring layers is restricted since, for example, the degree by which warping is reduced fluctuates according to differences in the number of interlayer insulating resin layers laminated on one side of the core substrate and the opposite side thereof; and this method cannot be used in the case of a double-sided board not using an interlayer insulating resin layer. In addition, since a prepreg containing glass cloth is used for the interlayer insulating resin layer, problems occur during via hole processing with a laser, thereby resulting in the risk of having an effect on inter-via hole reliability.

Moreover, since the built-up layer of the printed wiring board not only contains the interlayer insulating resin layer, but also a wiring layer (metal layer having a prescribed circuit pattern formed therein), the coefficient of linear expansion of the aforementioned wiring layer also has an effect on warping. Since the wiring layer is not a uniform, continuous film, but rather differs in terms of the shape of the circuit pattern and area for each layer, it is difficult to predict the effect of the wiring layer on stress.

In addition, since the number of wiring layers of the printed wiring board and the shape of the wiring pattern are subject to design restrictions, there are cases in which stress on one side of the core substrate and stress on the opposite side thereof are mutually antagonistic, and in such cases, the direction of warping becomes irregular for individual products even if they use printed wiring boards having the same specifications, and there are also cases in which both positive warping and negative warping occur simultaneously.

Thus, it is difficult to control the reduction in warping of a semiconductor device in the invention of Patent Document 1.

With the foregoing in view, an object of the present invention is to achieve at least one of any of the objects indicated below regardless of the physical properties or number of layers of the interlayer insulating resin layer.

A first object of the present invention is to provide an insulting substrate or metal-clad laminate capable of adequately reducing or preventing negative warping of a semiconductor device.

In addition, a second object of the present invention is to provide an insulating substrate or metal-clad laminate that is easily controlled to reduce or prevent negative warping of a semiconductor device.

In addition, a third object of the present invention is to provide a printed wiring board in which warping is controlled that is produced using the aforementioned insulating substrate or metal-clad laminate of the present invention.

In addition, a fourth object of the present invention is to provide a semiconductor device in which warping is reduced or prevented that is produced using the aforementioned insulating substrate or metal-clad laminate of the present invention.

### Means for Solving the Problems

The insulating substrate of the present invention is an insulating substrate composed of a cured product of a laminate comprising one or more fibrous base material layers and two or more resin layers, in which the outermost layers on both sides is the resin layers, wherein when the fibrous base material layers contained in the insulating substrate are defined as Cx moving in order from a first side (where, x is an integer represented by 1−n, and n is the number of the fibrous base material layers), and

when a total thickness (B3) of the insulating substrate is equally divided by the number (n) of the fibrous base material layers, and each divided region having the thickness (B4) is further equally divided by two, where the dividing position is defined as a reference position, and each reference position is defined as Ax in order from the first side (where, x is an integer represented by 1−n, and n is the number of the fibrous base material layers),

at least one of the fibrous base material layers (Cx) is shifted towards the first side or a second side on the opposite side thereof with respect to the reference position (Ax) of the corresponding order (x), and the fibrous base material layers (Cx) are not shifted in different directions.

In addition, in the insulating substrate of the present invention, at least one of the fibrous base material layers is shifted towards the first side with respect to the reference position of the corresponding order, and

in the shifted fibrous base material layer,

a ratio (B5/B6) of a thickness (B5) of a resin filled region on the first side of the fibrous base material layer to a thickness (B6) of a resin filled region on the second side of the fibrous base material layer is preferably such that 0.1<B5/B6<1.2.

In addition, in the insulating substrate of the present invention, the number of the fibrous base material layers is preferably 1 or 2.

In addition, in the insulating substrate of the present invention, one fibrous base material layer each is preferably present in each region of the equally divided thickness (B4).

In addition, in the insulating substrate of the present invention, at least one of each region of the equally divided thickness (B4) has a single fibrous base material layer shifted towards the first side with respect to the reference position of the corresponding order, and

in the shifted fibrous base material layer, a ratio (B7/B8) of a distance (B7) from an interface on the first side of the fibrous base material layer to an interface on the first side of a region of thickness (B4) to which the fibrous base material layer belongs, to a distance (B8) from an interface on the second side of the fibrous base material layer to an interface on the second side of a region of thickness (B4) to which the fibrous base material layer belongs, is preferably such that 0.1<B7/B8<0.9.

In addition, in the insulating substrate of the present invention, the fibrous base material layer as located closest to the first side among the fibrous base material layers possessed by the insulating substrate is preferably arranged to be shifted towards the first side with respect to the reference position of the corresponding order.

In addition, in the insulating substrate of the present invention, the fibrous base material layer as located closest to the second side among the fibrous base material layers possessed by the insulating substrate is preferably arranged to be shifted towards the first side with respect to the reference position of the corresponding order.

In addition, in the insulating substrate of the present invention, the total thickness is preferably 0.03 mm to 0.5 mm.

In addition, the insulating substrate of the present invention is an insulating substrate composed of a cured product of a single prepreg or a laminate obtained by superimposing two or more prepregs, wherein a first resin layer is provided on a first side of a fibrous base material layer and a second resin layer is provided on a second side, and at least one asymmetrical prepreg is contained in which the thickness of the first resin layer is smaller than the thickness of the second resin layer.

Namely, in the insulating substrate of the present invention, the laminate preferably consists of only a single prepreg or is obtained by laminating two or more prepregs, a first resin layer is provided on a first side of the fibrous base material layer and a second resin layer is provided on a second side, and at least one asymmetrical prepreg is contained in which the thickness of the first resin layer is smaller than the thickness of the second resin layer.

In addition, in a metal-clad laminate of the present invention, a metal foil layer is preferably provided on at least one side of the insulating substrate of the present invention.

In addition, in a printed wiring board of the present invention, one or two or more conductor circuit layers are preferably provided on at least one side of the insulating substrate of the present invention.

In addition, in a semiconductor device of the present invention, a semiconductor element is preferably mounted on the conductor circuit layer of the printed wiring board of the present invention.

In addition, in the semiconductor device of the present invention, a semiconductor element is preferably mounted on the conductor circuit layer provided on a second side being the opposite side of a first side located toward the direction in which a fibrous base material layer is shifted in the insulating substrate contained in the printed wiring board.

In addition, in the semiconductor device of the present invention, among the fibrous base material layers possessed by the insulating substrate contained in the printed wiring board, the fibrous base material layer as located closest to the first side is preferably arranged to be shifted towards the first side with respect to the reference position of the corresponding order, and

the semiconductor element is preferably mounted on a conductor circuit layer provided on a second side being the opposite side of the first side located toward the direction in which the fibrous base material is shifted.

### Effects of the Invention

According to the present invention, as a result of at least one fibrous base material layer contained by an insulating substrate being shifted towards a first side or a second side with respect to a reference position of the order corresponding to the fibrous base material layer, and not having any fibrous base material layers shifted in different directions, the insulating substrate and a printed wiring board that uses this insulating substrate are formed either warped outward in the direction in which the fibrous base material layer is shifted or flat, and the direction and degree of warping can be controlled. Thus, by aligning the direction in which the fibrous base material layer contained in the insulating substrate or the printed wiring board is shifted so as to be towards the opposite side from the side on which a semiconductor element is mounted, a printed wiring board prior to mounting of a semiconductor element is intentionally controlled to a state of positive warping or being flat, and as a result thereof, negative warping of a semiconductor device, in which a semiconductor element is mounted on the printed wiring board, is reduced or completely prevented.

In addition, according to the present invention, since there are no restrictions on circuit design, such as the number of conductor circuit layers or the circuit pattern, for controlling warping of a semiconductor, there is a high degree of design freedom.

### BRIEF DESCRIPTION OF THE DRAWINGS

FIG. 1A is a drawing schematically showing a cross-section of an example of an insulating substrate according to the present invention that contains one fibrous base material layer and two resin layers. FIG. 1B is a drawing showing a state in which the insulating substrate shown in FIG. 1A has warped at normal temperatures.

FIG. 2A is a drawing schematically showing a cross-section of an example of an insulating substrate according to the present invention that contains one fibrous base material layer and three resin layers. FIG. 2B is a drawing showing a state in which the insulating substrate shown in FIG. 2A has warped at normal temperatures.

FIG. 3A is a drawing schematically showing a cross-section of an example of an insulating substrate according to the present invention that contains two fibrous base material layers and four resin layers. FIG. 3B is a drawing showing a state in which the insulating substrate shown in FIG. 3A has warped at normal temperatures.

FIG. 4A is a drawing schematically showing a cross-section of an example of an insulating substrate according to the present invention that contains two fibrous base material layers and four resin layers. FIG. 4B is a drawing showing a state in which the insulating substrate shown in FIG. 4A has warped at normal temperatures.

FIG. 5A is a drawing schematically showing a cross-section of an example of an insulating substrate according to the present invention that contains three fibrous base material layers and six resin layers. FIG. 5B is a drawing showing a state in which the insulating substrate shown in FIG. 5A has warped at normal temperatures.

FIG. 6A s a drawing schematically showing a cross-section of an example of an insulating substrate according to the present invention that contains three fibrous base material layers and six resin layers. FIG. 6B is a drawing showing a state in which the insulating substrate shown in FIG. 6A has warped at normal temperatures.

FIG. 7 is a drawing that explains an example of a method for obtaining an asymmetrical prepreg used in the present invention.

FIG. 8 is a drawing that explains an example of a method for obtaining a laminate used in the present invention.

FIG. 9 is a drawing that explains another example of a method for obtaining a laminate used in the present invention.

FIG. 10 is a drawing that explains another example of a method for obtaining a laminate used in the present invention.

FIG. 11 is a drawing that explains another example of a method for obtaining a laminate used in the present invention.

FIG. 12 is a drawing schematically showing a cross-section of a semiconductor device in which a semiconductor element is mounted on printed wiring board having the insulating substrate shown in FIG. 1 as a core layer thereof.

FIG. 13 is a drawing schematically showing a cross-section of a semiconductor device in which a semiconductor element is mounted on printed wiring board having the insulating substrate shown in FIG. 5 as a core layer thereof.

FIG. 14 is a drawing schematically showing a cross-section of a semiconductor device in which a semiconductor element is mounted on printed wiring board having the insulating substrate shown in FIG. 6 as a core layer thereof.

FIG. 15A is drawing that explains positive warping of a semiconductor device, while FIG. 15B is a drawing that explains negative warping of a semiconductor device.

### DESCRIPTION OF THE EMBODIMENTS

### 1. Insulating Substrate

The insulating substrate of the present invention is an insulating substrate comprising one or more fibrous base material layers and two or more resin layers, the outermost layers on both sides being resin layers, wherein

when the fibrous base material layers contained in the insulating substrate are defined as Cx moving in order from a first side (where, x is an integer represented by 1−n, and n is the number of fibrous base material layers), and

a dividing position when a total thickness (B3) of the insulating substrate is equally divided by the number (n) of the fibrous base material layers and the thickness (B4) of each divided region is further equally divided by two is defined as a reference position, and each reference position is defined as Ax in order from the first side (where, x is an integer represented by 1−n, and n is the number of fibrous base material layers),

at least one of the fibrous base material layers (Cx) is shifted towards the first side or a second side on the opposite side thereof with respect to the reference position (Ax) of the corresponding order (x), and the fibrous base material layers (Cx) are not shifted in different directions.

In other words, the reference position of each fibrous base material layer is a position of a height calculated using the following equation from a first side of the insulating substrate of the present invention:

Reference position(Ax)=(total thickness B3)÷number of fibrous base material layers(n))×(integer(x)representing order of fibrous base material layer−0.5)

Furthermore, in the case the insulating substrate of the present invention has a plurality of fibrous base material layers, if at least one of the fibrous base material layers is shifted towards a first side or second side with respect to the reference position of the corresponding order, then the other fibrous base material layers may be provided at the reference position of the corresponding order.

The insulating substrate of the present invention has the property of warping outward in the direction in which the fibrous base material is shifted when cooled after having undergone heated pressure molding in the production process thereof. Since the coefficient of linear expansion of the resin layer is greater than the coefficient of linear expansion of the fibrous base material layer, when the insulating substrate is cooled to normal temperature from a stress-free state during heated pressure molding, the resin layer shrinks more than the fibrous base material layer. Consequently, the overall insulating substrate warps outward in the direction in which the fibrous base material layer is shifted.

The insulating substrate of the present invention enables warping of the insulating substrate to be controlled by utilizing this property and adjusting the position of the fibrous base material layer.

The following provides a detailed explanation of the insulating substrate of the present invention based on the drawings.

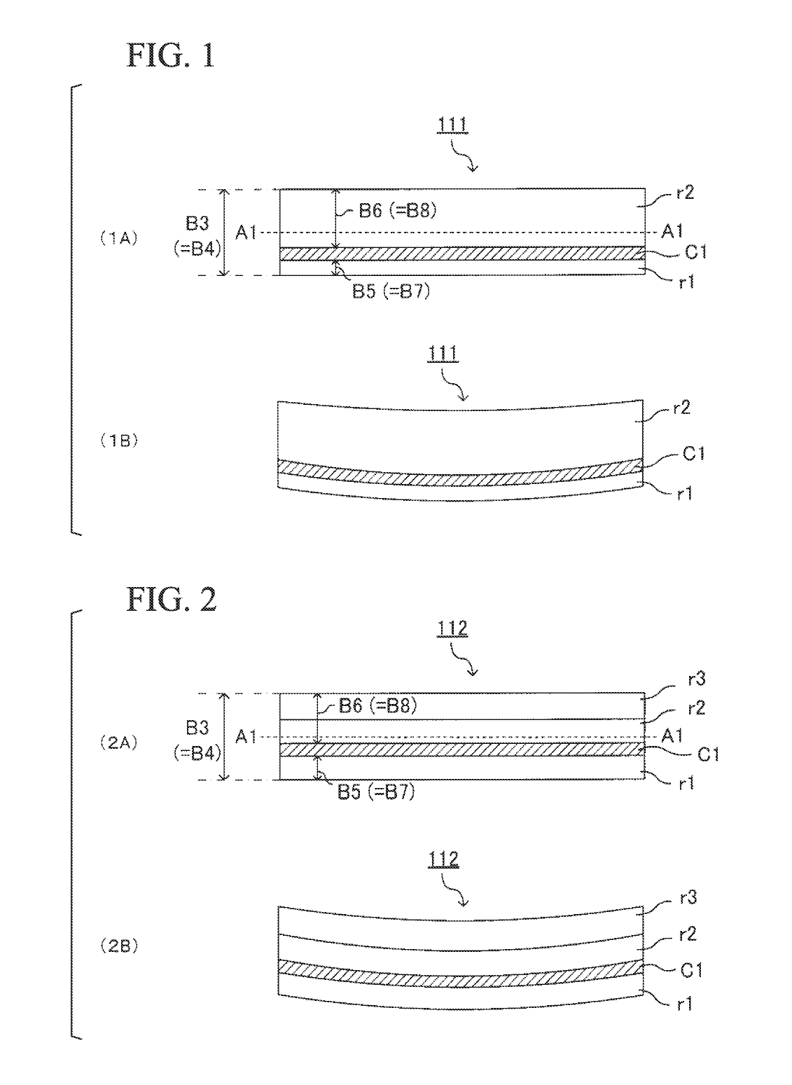

FIG. 1 is a drawing schematically showing a cross-section of an insulating substrate composed of one fibrous base material layer and two resin layers as an example of the insulating substrate of the present invention. An insulating substrate 111 shown in FIG. 1A has a layer composition obtained by laminating from a first side a resin layer r1, a fibrous base material layer C1 and a resin layer r2 in that order. The fibrous base material layer C1 is shifted towards the direction of the first side (side of the resin layer r1) with respect to a reference position baseline A-1-A-1 of the corresponding order. Since the insulating substrate 111 only has one fibrous base material layer, the thickness B4 of each region obtained by equally dividing the total thickness B3 by the number of fibrous base material layers is equal to the total thickness B3.

In the insulating substrate 111 shown in FIG. 1A, since the resin layers contract more than the fibrous base material layer when cooled after being subjected to heated pressure molding in the production process thereof, at normal temperatures, the insulating substrate 111 has the property of warping outward in the direction in which the fibrous base material layer C1 is shifted as shown in FIG. 1B.

FIG. 2 is a drawing schematically showing a cross-section of an insulating substrate composed of one fibrous base material layer and three resin layers as an example of the insulating substrate of the present invention containing one fibrous base material layer. An insulating substrate 112 shown in FIG. 2A has a layer composition obtained by laminating from a first side a resin layer r1, the fibrous base material layer C1, and resin layers r2 and r3 in that order. The fibrous base material layer C1 is shifted towards the first side (side of the resin layer r1) with respect to the reference position baseline A1-A1 of the corresponding order. Since the insulating substrate 112 has only one fibrous base material layer, the thickness B4 of each region obtained by equally dividing the total thickness B3 by the number of fibrous base material layers is equal to the total thickness B3.

The insulating substrate 112 shown in FIG. 2B, since the resin layers contract more than the fibrous base material layer when cooled after being subjected to heated pressure molding in the production process thereof, at normal temperatures, the insulating substrate 112 has the property of warping outward in the direction in which the fibrous base material layer C1 is shifted as shown in FIG. 2B.

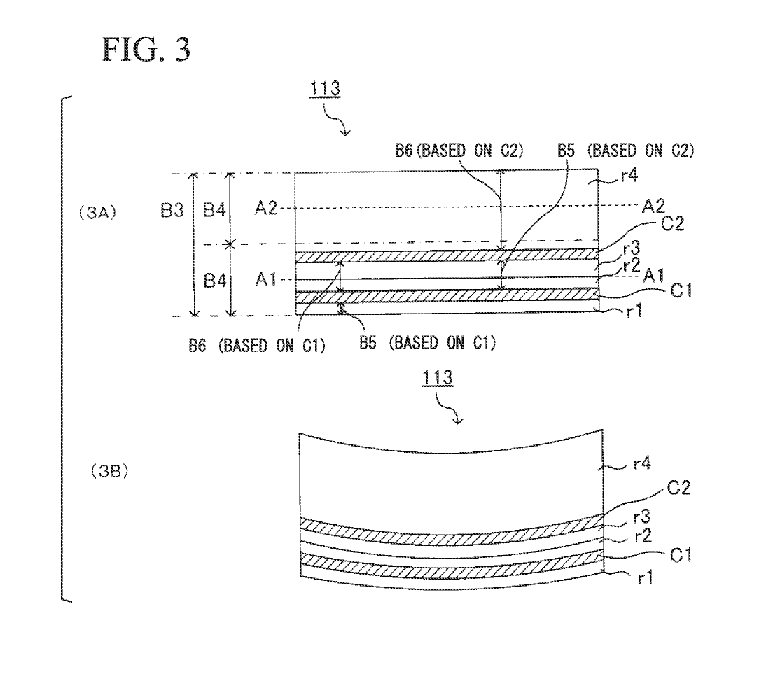

The insulating substrate of the present invention may also contain a portion obtained by laminating a plurality of resin layers as in the manner of the resin layers r2 and r3 shown in FIG. 2A or the resin layers r2 and r3 shown in FIG. 3A to be subsequently described. In the present invention, laminating a plurality of resin layers refers to laminating a plurality of resin layers at the production stage prior to curing the insulating substrate, and the interfaces of the plurality of resin layers are not required to be able to be confirmed in a cross-section of the insulating substrate after curing.

FIG. 3 is a drawing schematically showing a cross-section of an insulating substrate composed of two fibrous base material layers and four resin layers as another example of the insulating substrate of the present invention. An insulating substrate 113 shown in FIG. 3A has a layer composition obtained by laminating from a first side the resin layer r1, the fibrous base material layer C1, the resin layers r2 and r3, a fibrous base material layer C2 and a resin layer r4 in that order. The fibrous base material layer C1 is shifted towards the first side (side of the resin layer r1) with respect to the reference position baseline A1-A1 of the corresponding order, and the fibrous base material layer C2 is also shifted towards the first side (side of the resin layer r3) with respect to a reference position baseline A2-A2 of the corresponding order, or in other words, the fibrous base material layers C1 and C2 are shifted in the same direction. The thickness of each region obtained by equally dividing the total thickness B3 of the insulating substrate 113 by the number of fibrous base material layers, namely the thickness of each region obtained by equally dividing the total thickness B3 by two, is indicated as B4. The fibrous base material layers C1 and C2 are both present within a region of thickness B4 on the first side, while fibrous base material layers are not present in a region of thickness B4 on a second side.

In the insulating substrate 113 shown in FIG. 3A, since the resin layers contract more than the fibrous base material layers when cooled after being subjected to heated pressure molding in the production process thereof, at normal temperatures, the insulating substrate 113 has the property of warping outward in the direction in which the fibrous base material layers C1 and C2 are shifted as shown in FIG. 3B.

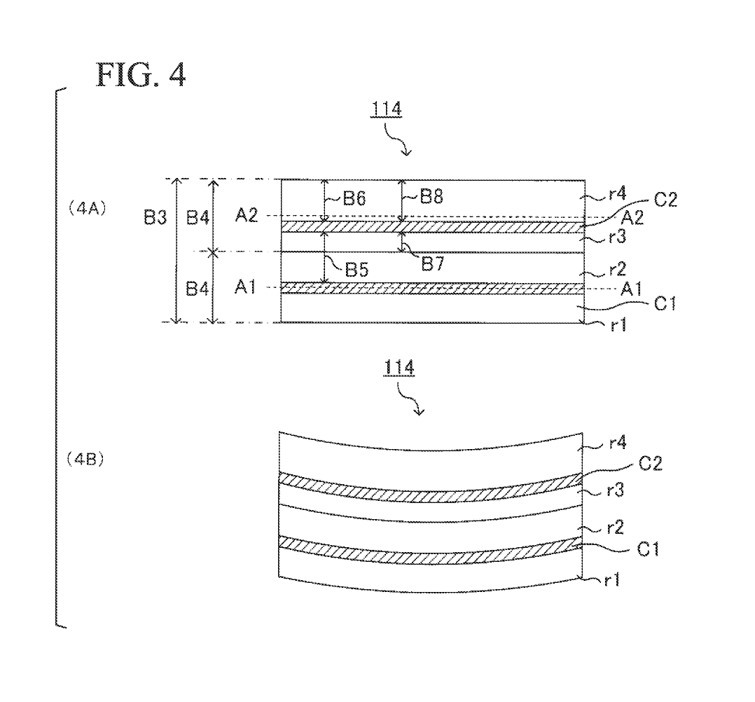

FIG. 4 is a drawing schematically showing a cross-section of another example of the insulating substrate of the present invention that contains two fibrous base material layers and four resin layers. An insulating substrate 114 shown in FIG. 4A has a layer composition obtained by laminating from a first side the resin layer r1, the fibrous base material layer C1, the resin layers r2 and r3, the fibrous base material layer C2 and the resin layer r4 in that order. The fibrous base material layer C1 is present on the reference position baseline A1-A1 of the corresponding order, while the fibrous base material layer C2 is also shifted towards the first side (side of the resin layer r3) with respect to the reference position baseline A2-A2 of the corresponding order. The thickness of each region obtained by equally dividing the total thickness B3 of the insulating substrate 114 by the number of fibrous base material layers, namely the thickness of each region obtained by equally dividing the total thickness B3 by two, is indicated as B4. One each of the fibrous base material layers C1 and C2 is respectively present within each region of thickness B4.

In the insulating substrate 114 shown in FIG. 4A, since the resin layers contract more than the fibrous base material layers when cooled after being subjected to heated pressure molding in the production process thereof, at normal temperatures, the insulating substrate 114 has the property of warping outward in the direction in which the fibrous base material layer C2 is shifted as shown in FIG. 4B.

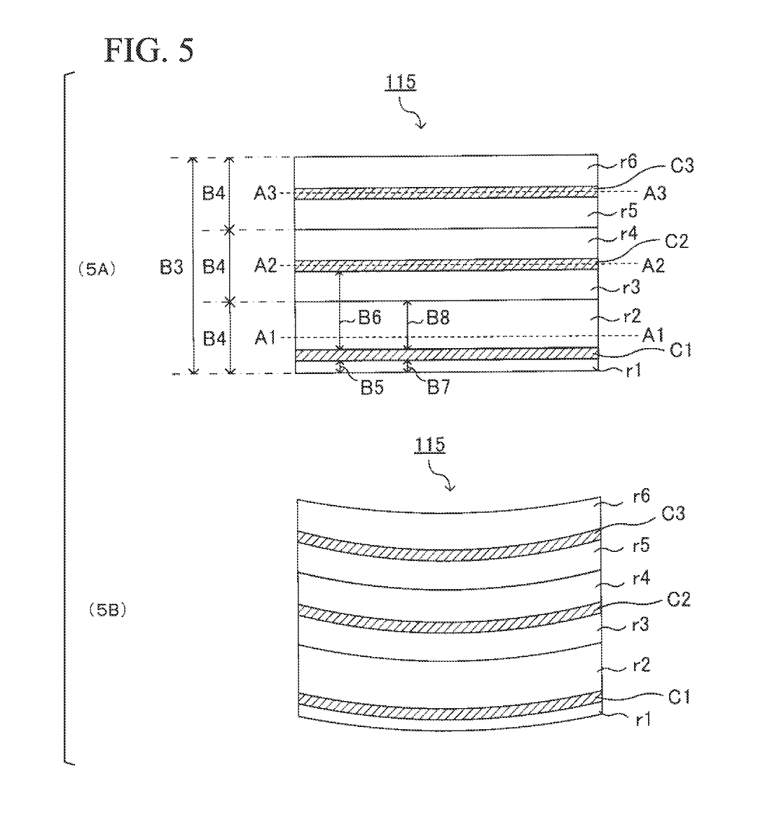

FIG. 5 is a drawing schematically showing a cross-section of an insulating substrate composed of three fibrous base material layers and six resin layers as another example of the insulating substrate of the present invention. An insulating substrate 115 shown in FIG. 5A has a layer composition obtained by laminating from a first side the resin layer r1, the fibrous base material layer C1, the resin layers r2 and r3, the fibrous base material layer C2, resin layers r4 and r5, a fibrous base material layer C3, and a resin layer r6 in that order. Among the fibrous base material layers C1, C2 and C3, the fibrous base material layer C1 located closest to the first side is shifted towards the first side (side of the resin layer r1) with respect to the reference position baseline A1-A1 of the corresponding order, while the fibrous base material layers C2 and C3 are respectively present on the reference position baseline A2-A2 and a reference position baseline A3-A3 of the corresponding order. The thickness of each region obtained by equally dividing the total thickness B3 of the insulating substrate 115 by the number of fibrous base material layers, namely the thickness of each region obtained by equally dividing the total thickness B3 by three, is indicated as B4. One each of the fibrous base material layers C1, C2 and C3 is respectively present within each region of thickness B4.

In the insulating substrate 115 shown in FIG. 5A, since the resin layers contract more than the fibrous base material layers when cooled after being subjected to heated pressure molding in the production process thereof, at normal temperatures, the insulating substrate 115 has the property of warping outward in the direction in which the fibrous base material layer C1 is shifted as shown in FIG. 5B.

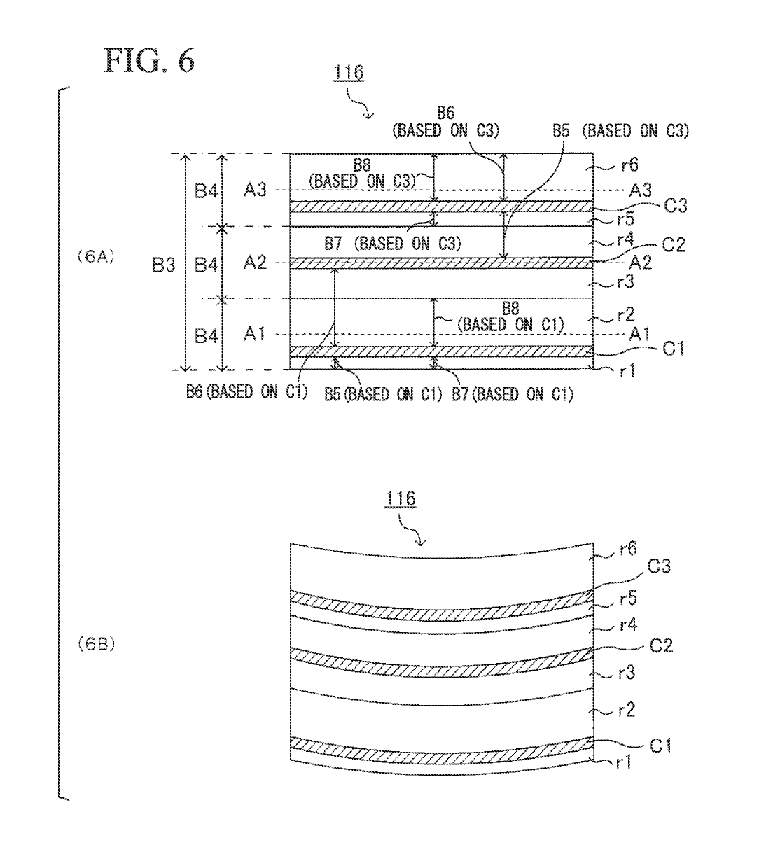

FIG. 6 is a drawing schematically showing a cross-section of another example of an insulating substrate of the present invention containing three fibrous base material layers and six resin layers. An insulating substrate 116 shown in FIG. 6A has a layer composition obtained by laminating from a first side the resin layer r1, the fibrous base material layer C1, the resin layers r2 and r3, the fibrous base material layer C2, the resin layers r4 and r5, and the fibrous base material layer C3 in that order. Among the fibrous base material layers C1, C2 and C3, the fibrous base material layer C1 located closest to the first side is shifted towards the first side (side of the resin layer r1) with respect to the reference position baseline A1-A1 of the corresponding order, and fibrous base material layer C3 located closest to a second side is shifted towards the first side (side of the resin layer r5) with respect to the reference position baseline A3-A3 of the corresponding order, or in other words, the fibrous base material layers C1 and C3 are shifted in the same direction. The fibrous base material layer C2 is located on the reference position baseline A2-A2 of the corresponding order. The thickness of each region obtained by equally dividing the total thickness B3 of the insulating substrate 116 by the number of fibrous base material layers, namely the thickness of each region obtained by equally dividing the total thickness B3 by three, is indicated as B4. One each of the fibrous base material layers C1, C2 and C3 is respectively present within each region of thickness B4.

In the insulating substrate 116 shown in FIG. 6A, since the resin layers contract more than the fibrous base material layers when cooled after being subjected to heated pressure molding in the production process thereof, at normal temperatures, the insulating substrate 116 has the property of warping outward in the direction in which the fibrous base material layers C1 and C3 are shifted as shown in FIG. 6B.

Although there are no particular limitations thereon, in the insulating substrate of the present invention, at least one of the aforementioned fibrous base material layers is shifted towards the first side with respect to a reference position of the corresponding order, and a ratio (B5/B6) of thickness (B5) of a resin filled region on a first side of the aforementioned fibrous base material layers to a thickness (B6) of a resin filled region on a second side of the aforementioned fibrous base material layers is preferably such that 0.1<B5/B6<1.2.

Furthermore, in the present invention, a “resin filled region” refers to the distance from an interface of a fibrous base material layer to an interface of an adjacent fibrous base material layer or air layer. The aforementioned resin filled region may be composed of one resin layer, or may be composed by laminating a plurality of resin layers. In addition, in the present invention, an “interface” refers to a flat surface in which surface irregularities in a surface serving as the interface between a resin layer and a fibrous base material layer or air layer have been leveled.

B5 and B6 based on fibrous base material layers that are respectively shifted are shown in each of the insulating substrates shown in FIGS. 1A, 2A, 3A, 4A, 5A and 6A. Furthermore, B5 and B6 respectively based on shifted fibrous base material layers are shown for the insulating substrate 113 shown in FIG. 3A and the insulating substrate 116 shown in FIG. 6A since two fibrous base material layers are shifted therein.

Furthermore, although there are cases in the insulating substrate of the present invention in which B5/B6 is 1 or more, examples of such cases include the case of the insulating substrate 114 shown in FIG. 4A, and the case of being based on the fibrous base material layer C3 in the insulating substrate 116 shown in FIG. 6A.

In the case B5/B6 is less than the aforementioned lower limit value in the insulating substrate of the present invention, since this means that a fibrous base material layer is extremely shifted, warping of the insulating substrate may be excessively large. On the other hand, in the case B5/B6 exceeds the aforementioned upper limit value, the distance between fibrous base material layers becomes excessively large, thereby making it difficult to control warping. Accordingly, if B5/B6 is within the aforementioned range, warping of the insulating substrate is easily controlled since the fibrous base material layers are arranged in proper balance.

Although there are no particular limitations thereon in the insulating substrate of the present invention, one fibrous base material layer each is preferably present in each region of the thickness B4 obtained by equally dividing the total thickness (B3) by the number of fibrous base material layers (to be simply referred to as a “region of thickness B4” or a “B4 region”) from the viewpoint of facilitating control of warping without causing warping of the insulating substrate to become excessively large.

Although there are no particular limitations thereon in the insulating substrate of the present invention, at least one of each region of the thickness B4 preferably has one fibrous base material layer shifted towards a first side with respect to a reference position of the corresponding order, and in the aforementioned shifted fibrous base material layer, a ratio (B7/B8) of a distance (B7), from an interface on the first side of the aforementioned fibrous base material layer to an interface on the aforementioned first side of a region of thickness B4 to which the aforementioned fibrous base material layer belongs, to a distance (B8), from an interface on a second side of the aforementioned fibrous base material layer to an interface on the aforementioned second side of a region of thickness B4 to which the aforementioned fibrous base material layer belongs, is preferably such that 0.1<B7/B8<0.9 from the viewpoint of facilitating control of warping without causing warping of the insulating substrate to become excessively large.

B7 and B8 when based on fibrous base material layers that are respectively shifted are indicated for each of the insulating substrates shown in FIGS. 1A, 2A, 4A, 5A and 6A. Furthermore, B7 and B8 cannot be specified in the case there are no fibrous base material layers present or a plurality of fibrous base material layers are present in a region of thickness B4 in the manner of the insulating substrate 113 shown in FIG. 3A. The values of B7 and B8 are equal to the values of B5 and B6, respectively, in the case the insulating substrate has only one fibrous base material layer in the manner of the insulating substrate 111 shown in FIG. 1A and the insulating substrate 112 shown in FIG. 2A.

In addition, in the case the insulating substrate of the present invention has a plurality of fibrous base material layers, the fibrous base material layer located closest to a first side among the aforementioned plurality of fibrous base material layers is preferably arranged shifted towards the aforementioned first side with respect to a reference position of the corresponding order from the viewpoint of reliably controlling the direction of warping of the insulating substrate.

From the same viewpoint, the fibrous base material layer located closest to the first side among the aforementioned plurality of fibrous base material layers is particularly preferably arranged shifted towards the aforementioned first side with respect to a reference position of the corresponding order, and the fibrous base material layer located closest to a second side is particularly preferably arranged on the aforementioned first side from the reference position of the corresponding order.

Although there are no particular limitations thereon, the total thickness (B3) of the insulating substrate of the present invention is normally 0.03 mm to 0.5 mm and preferably 0.04 mm to 0.4 mm.

Although there are no particular limitations thereon, the thickness (B4) of each region obtained by dividing the total thickness (B3) of the insulating substrate of the present invention by the number of fibrous base material layers is normally 5 μm to 200 μm.

A resin layer possessed by the insulating substrate of the present invention is a layer obtained by curing a heat-curable or photosensitive curable resin composition and the like. On the other hand, a fibrous base material layer possessed by the insulating substrate of the present invention is a layer obtained by impregnating a fibrous base material with the aforementioned curable resin composition and curing.

In addition, the insulating substrate of the present invention may be formed with a curable resin composition in which a resin layer on a first side of a fibrous base material layer and a resin layer on a second side are different. In the case of laminating a plurality of adjacent resin layers, the adjacent resin layers may be formed with mutually different curable resin compositions within a range that does not affect adhesion between resin layers. In addition, the fibrous base material layer may be impregnated with a curable resin composition that forms either a resin layer on the first side or a resin layer on the second side, or the fibrous base material layer may be impregnated with a resin that forms a resin layer on the first side and a resin that forms a resin layer on the second side, and the two types of resins may be contacted or mixed within the fibrous base material layer.

Although there are no particular limitations thereon, a material having heat resistance able to withstand the production process and usage conditions of semiconductor devices is selected for the aforementioned fibrous base material. Examples of such fibrous base materials include fibrous base materials including glass fibrous base materials such as glass woven fabric or glass non-woven fabric; synthetic fibrous base materials composed of a woven fabric or non-woven fabric composed mainly of polyamide-based resin fibers such as polyamide resin fibers, aromatic polyamide resin fibers or fully aromatic polyamide fibers, polyester-based resin fibers such as polyester resin fibers, aromatic polyester resin fibers or fully aromatic polyester resin fibers, polyimide resin fibers, fluororesin fibers or polybenzoxazole resin fibers; and organic fibrous base materials such as paper base materials composed mainly of kraft paper, cotton linter paper or mixed paper of linter and kraft paper; and, resin films such as those made of polyester or polyimide. Among these, glass fibrous base materials are preferable. As a result, strength of the insulating substrate can be improved and the coefficient of linear expansion of the insulating substrate can be lowered.

Examples of glass used to compose glass fibrous base materials include E glass, C glass, A glass, S glass, D glass, NE glass, T glass, H glass and quartz glass. Among these, a high elastic modulus can be achieved for the glass fibrous base material and the coefficient of linear expansion can be lowered in the case of using E glass or T glass in particular.

Although there are no particular limitations thereon, the thickness of the aforementioned fibrous base material used is normally about 5 μm to 200 μm, and in the case of desiring to reduce the thickness of the core layer (portion containing an insulating substrate) of a printed wiring board in particular, the thickness is preferably about 5 μm to 100 μm.

Although a curable resin composition such as heat-curable or photosensitive resin composition is used for the aforementioned curable resin composition, a heat-curable resin composition is used normally. Heat-curable resin compositions normally contain a heat-curable resin, curing agent, filler and the like.

Examples of heat-curable resins used include epoxy resin, cyanate resin, bismaleimide resin, phenol resin, benzoxazine resin, polyimide resin and polyamide-imide resin, and epoxy resin is used normally in a suitable combination with other heat-curable resins.

Although there are no particular limitations thereon, the aforementioned epoxy resin is an epoxy resin substantially free of halogen atoms, examples of which include bisphenol-based epoxy resins such as bisphenol A epoxy resin, bisphenol F epoxy resin, bisphenol E epoxy resin, bisphenol S epoxy resin, bisphenol Z epoxy resin (4,4′-cyclohexidiene bisphenol epoxy resin), bisphenol P epoxy resin (4,4′-(1,4-phenylenediisoprediene)bisphenol epoxy resin) or bisphenol M epoxy resin (4,4′-(1,3-phenylenediisoprediene)bisphenol epoxy resin, novolac-type epoxy resins such as phenol novolac epoxy resin or cresol novolac epoxy resin, aryl alkylene epoxy resins such as biphenyl epoxy resin, xylylene epoxy resin, xylylene epoxy resin, phenol aralkyl epoxy resin, biphenyl aralkyl epoxy resin, biphenyl dimethylene epoxy resin, biphenyl aralkyl novolac epoxy resin, trisphenol methane novolac epoxy resin, glycidyl ethers of 1,1,2,2-(tetraphenol)ethane, trifunctional or tetrafunctional glycidyl amines or tetramethyl biphenyl epoxy resin, naphthalene-based epoxy resins such as naphthalene-skeleton-modified cresol novolac epoxy resin, methoxynaphthalene-modified cresol novolac epoxy resin, methoxynaphthalene dimethylene epoxy resin or naphthol alkylene epoxy resin, anthracene epoxy resin, phenoxy epoxy resin, dicyclopentadiene epoxy resin, norbornene epoxy resin, adamantan epoxy resin, fluorene epoxy resin, and flame retardant epoxy resins obtained by halogenating the aforementioned epoxy resins. One type of these resins can be used alone, two or more types having different weight average molecular weights can be used in combination, or one type or two or more types can be used in combination with prepolymers thereof.

Among these epoxy resins, novolac epoxy resins are preferable, biphenyl aralkyl novolac epoxy resins are more preferable, and biphenyl dimethylene epoxy resins are particularly preferable.

Biphenyl aralkyl novolac epoxy resins refer to epoxy resins having one or more biphenyl alkylene groups in repeating units thereof. Examples thereof include xylylene epoxy resins and biphenyl dimethylene epoxy resins. Biphenyl dimethylene epoxy resins can be represented by the following formula (I):

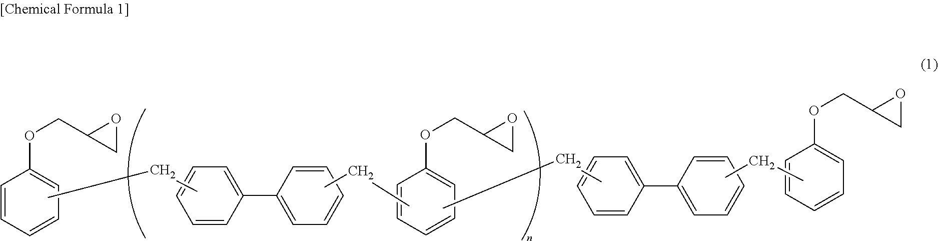

(wherein, n represents an arbitrary integer).

Although there are no particular limitations thereon, the average number of repeating units n of the biphenyl dimethylene epoxy resin represented by the aforementioned formula (I) is preferably 1 to 10 and particularly preferably 2 to 5. If the average number of repeating units n is less than the aforementioned lower limit value, the biphenyl dimethylene epoxy resin crystallizes easily and solubility in general-purpose solvents decreases, thereby resulting in handling difficulty. In addition, if the average number of repeating units n exceeds the aforementioned upper limit value, resin fluidity decreases, and this may cause defective molding and the like.

Although there are no particular limitations thereon, the molecular weight of the epoxy resin is preferably such that the weight average molecular weight is within the range of 5.0×10² to 2.0×10⁴. The weight average molecular weight of novolac epoxy resins can be measured by, for example, gel permeation chromatography (GPC, standard: polystyrene).

In addition, although there are no particular limitations thereon, the content of epoxy resin is preferably 1% by weight to 65% by weight of the solid content of the heat-curable resin composition.

As a result of containing a cyanate resin in the heat-curable resin composition of the present invention, incombustibility can be improved, linear coefficient of expansion can be lowered, and electrical properties of the resin layer (low dielectric constant, low dielectric tangent) can be improved. Although there are no particular limitations thereon, the aforementioned cyanate resin can be obtained by, for example, reacting a cyanogen halide compound with a phenol and a naphthol, and heating as necessary to form a prepolymer. In addition, a commercially available product prepared in this manner can also be used.

Although there are no particular limitations thereon, examples of types of the aforementioned cyanate resins include novolac cyanate resins, bisphenol cyanate resins such as bisphenol A cyanate resin, bisphenol E cyanate resin or tetramethyl bisphenol F cyanate resin, and naphthol aralkyl cyanate resins. Novolac cyanate resins allow the linear coefficient of expansion of the resin layer to be lowered, and are also superior in terms of mechanical strength and electrical properties (low dielectric constant, low dielectric tangent) of the resin layer.

The aforementioned cyanate resin preferably has two or more cyanate groups (—O—ON) in a molecule thereof. Examples thereof include 2,2′-bis(4-cyanatophenyol)isopropylidene, 1,1′-bis(4-cyanatophenyl)ethane, bis(4-cyanato-3,5-dimethylphenyl)methane, 1,3-bis(4-cyanatophenyl-(1-methylethylidene))benzene, dicyclopentadiene cyanate ester, phenol novolac cyanate ester, bis(4-cyanatophenyl)thioether, bis(4-cyanatophenyl)ether, 1,1,1-tris(4-cyanatophenyl) sulfone, 2,2-bis(4-cyanatophenyl)propane, 1,3-, 1,4-, 1,6-, 1,8-, 2,6- or 2,7-dicyanatonapthalene, 1,3,6-tricyanatonaphthalene, 4,4-dicyanatobiphenyl, cyanate resins obtained by reacting phenol novolac and cresol novolac polyvalent phenols with a cyanogen halide, and cyanate resins obtained by reacting naphthol aralkyl polyvalent naphthol with a cyanogen halide. Among these, phenol novolac cyanate resins are superior in terms of incombustibility and low thermal expansion, while 2,2-bis(4-cyanatophenyl)isopropylidene and dicyclopentadiene cyanate ester are superior in terms of control of crosslink density and moisture resistance reliability. Phenol novolac cyanate resins are particularly preferable from the viewpoint of low thermal expansion. In addition, one type or two or more types of other cyanate resins can also be used in combination without any particular limitations thereon.

The aforementioned cyanate resin can be used alone, different types of cyanate resins can be used in combination, or cyanate resin can be used in combination with another prepolymer.

The aforementioned prepolymer is normally obtained by, for example, trimerizing the aforementioned cyanate resin by a heating reaction and the like, and is preferably used in order to adjust varnish moldability and fluidity.

Although there are no particular limitations thereon, the aforementioned prepolymer is able to demonstrate favorable moldability and fluidity in the case of using at a trimerization rate of 20% by weight to 50% by weight.

Although there are no particular limitations thereon, the content of the aforementioned cyanate resin is preferably 5% by weight to 42% by weight based on the total solid content of the heat-curable resin composition.

The curing agent contained in the heat-curable resin composition is a heat-curable resin curing agent, and in addition to a compound that cures a resin composition by reacting with an epoxy group, for example, also uses a curing accelerator that accelerates the reaction between epoxy groups.

There are no particular limitations on the curing agent contained in the heat-curable resin composition, and examples include organic metal salts such as cobalt naphthenate, tin octylate, cobalt octylate, bis(acetylacetonato)cobalt(II) or tris(acetylacetonato)cobalt(III), tertiary amines such as triethylamine, tributylamine or diazabicyclo[2.2.2]octane, imidazoles such as 2-methylimidazole, 2-phenylimidazole, 2-phenyl-4-methylimidazole, 2-ethyl-4-ethylimidazole, 1-benzyl-2-methylimidazole, 1-benzyl-2-phenylimidazole, 2-undecylimidazole, 1-cyanoethyl-2-ethyl-4-methylimidazole, 1-cyanoethyl-2-undecylimidazole, 2-phenyl-4-methyl-5-hydroxyimidazole, 2-phenyl-4,5-dihydroxyimidazole or 2,3-dihydro-1H-pyrrolo[1,2-a]benzimidazole, phenol compounds such as phenol, bisphenol A or nonyl phenol, organic acids such as acetic acid, benzoic acid, salicylic acid or para-toluenesulfonic acid, and mixtures thereof.

Although there are no particular limitations thereon, the amount of curing agent is preferably 0.05% by weight to 4% by weight based on the total solid content of the heat-curable resin composition in the case of using an organic metal salt or imidazole. In addition, in the case of using a phenol compound or organic acid, the amount of curing agent is preferably 3% by weight to 40% by weight based on the total solid content of the heat-curable resin composition.

Although there are no particular limitations thereon, examples of filler contained in the heat-curable resin composition include inorganic fillers in the manner of silicates such as talc, baked clay, unbaked clay, mica or glass; oxides such as titanium oxide, alumina, boehmite, silica or fused silica; carbonates such as calcium carbonate, magnesium carbonate or hydrotalcite; hydroxides such as aluminum hydroxide, magnesium hydroxide or calcium hydroxide; sulfates or sulfites such as barium sulfate, calcium sulfate or calcium sulfite; borates such as zinc borate, barium metaborate, aluminum borate, calcium borate or sodium borate; nitrides such as aluminum nitride, boron nitride, silicon nitride or carbon nitride; and titanates such as barium titanate.

Although there are no particular limitations thereon, the particle diameter of the aforementioned inorganic filler is such that the mean particle diameter is preferably 0.005 μm to 10 μm, and particularly preferably spherical silica having a mean particle diameter of 5.0 μm or less. Furthermore, mean particle diameter can be measured with, for example, a particle size analyzer (Horiba, Ltd., LA-500).

Although there are no particular limitations thereon, the content of the filler is preferably 20% by weight to 80% by weight based on the total solid content of the aforementioned heat-curable resin composition.

The heat-curable resin composition may also contain other components as necessary, examples of which include a coupling agent for improving wettability with inorganic filler, a colorant for coloring the resin composition, as well as an antifoaming agent, leveling agent and flame retardant.

(Insulating Substrate Production Method)

As a result of using the aforementioned fibrous base material and the aforementioned curable resin composition, the insulating substrate of the present invention can be obtained by forming a laminate having a layer composition containing one or more fibrous base material layers and two or more resin layers, the outermost layers on both sides being resin layers, at least one of the fibrous base material layers being shifted towards a first side or a second side with respect to a reference position of the corresponding order, and the fibrous base material layers not being shifted in different directions, and curing the aforementioned laminate by heated pressure molding. Furthermore, the curable resin composition possessed by the aforementioned laminate prior to heated pressure molding is in the state of stage B. This laminate prior to heated pressure molding is hereinafter simply referred to as a “laminate”.

An example of a method used to obtain the aforementioned laminate is a method that uses a prepreg.

A prepreg typically refers to that which is obtained by impregnating an impregnable base material such as a fibrous base material with a resin composition containing a heat-curable resin and the like, forming a resin layer obtained by loading an excess amount of resin composition unable to be impregnated on one side or both sides of the aforementioned base material as necessary, and curing or drying to the state of stage B.

Prepregs used to obtain the aforementioned laminate consist of asymmetrical prepregs and symmetrical prepregs. In the present invention, an asymmetrical prepreg refers to a prepreg in which the thickness of the resin layer provided on a first side of the base material layer and the thickness of the resin layer provided on a second side are different. Namely, an asymmetrical prepreg refers to a prepreg in which the base material layer is shifted with respect to the direction of thickness of the prepreg.

On the other hand, a symmetrical prepreg refers to a prepreg in which the thicknesses of the resin layers provided on both sides of the base material layer are mutually equal. In addition, in the present invention, a prepreg in which hardly any of the resin layers protrude from the base material layer in the direction of thickness also refers to a symmetrical prepreg.

In the present invention, a prepreg fabricated using the aforementioned fibrous base material and the aforementioned curable resin composition can be used. When impregnating the aforementioned fibrous base material with the aforementioned curable resin composition, the aforementioned curable resin composition is dissolved in a solvent to obtain a varnish, and the aforementioned fibrous base material is impregnated with the aforementioned varnish.

Although the solvent used to obtain a varnish of the aforementioned curable resin composition preferably demonstrates favorable solubility and dispersibility at least with respect to the aforementioned heat-curable resin composition, a poor solvent may also be used within a range that does not have a detrimental effect. Specific examples of solvents that can be used include organic solvents such as alcohols, ethers, acetals, ketones, esters, alcohol esters, ketone alcohols, ether alcohols, ketone ethers, ketone esters or ester ethers. Examples of solvents that demonstrate favorable solubility include acetone, methyl ethyl ketone, methyl isobutyl ketone, cyclopentanone, dimethylformamide, dimethylacetoamide, N-methylpyrrolidone, ethylene glycol monomethyl ether and ethylene glycol monobutyl ether.

Although there are no particular limitations thereon, the solid (non-volatile component) concentration of the aforementioned varnish is normally about 30% by weight to 80% by weight.

An asymmetrical prepreg and symmetrical prepreg used in the present invention can be fabricated according to the methods described below.

(Asymmetrical Prepreg)

In the asymmetrical prepreg, a comparatively thin resin layer is referred to as first resin layer, while a comparatively thick resin layer is referred to as a second resin layer. In addition, a curable resin composition used to form the aforementioned first resin layer is referred to as a first resin composition, while a curable resin composition for forming the aforementioned second resin layer is referred to as a second resin composition.

Since the thicknesses of the resin layers on both sides of an asymmetrical prepreg differ, it is difficult to fabricate simply by impregnating varnish with a fibrous base material.

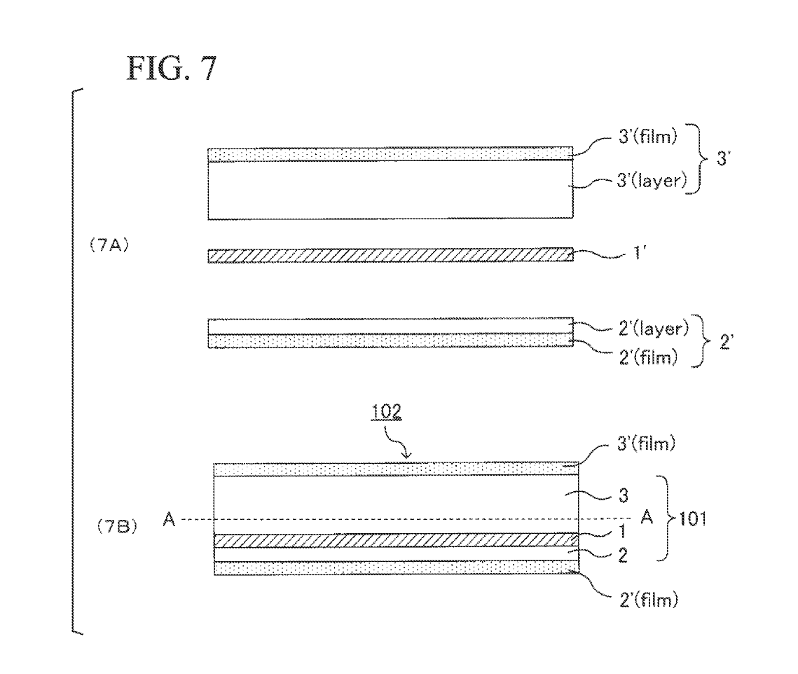

FIG. 7 shows an example of a method for obtaining an asymmetrical prepreg. In this method, first carrier material 2′, obtained by coating a varnish of the first resin composition onto a carrier film 2′ (film), and a second carrier material 3′, obtained by coating a varnish of the second resin composition onto a carrier film 3′ (film), are first produced as shown in FIG. 7A. In addition, a fibrous base material 1′ is prepared. Next, as shown in FIG. 7B, by laminating the first and second carrier materials on the aforementioned fibrous base material 1′ so that the varnish coated layers 2′ (layer) and 3′ (layer) are facing the fibrous base material 1′, an asymmetrical prepreg 102 having carrier films is obtained in which the carrier films 2′ (film) and 3′ (film) are respectively laminated on the surface of the first resin layer 2 and the surface of the second resin layer 3 of an asymmetrical prepreg 101. A fibrous base material layer 1 of the asymmetrical prepreg 101 is shifted toward the side of the first resin layer 2 from a line A-A obtained by dividing the thickness of the asymmetrical prepreg by two.

The carrier films may also be removed by a method such as peeling as necessary after the asymmetrical prepreg has been obtained. For example, carrier films other than carrier films located on the outermost surfaces of a prepreg laminate may be completely removed from the prepreg in advance followed by layering the prepregs at the stage at which two or more prepregs including an asymmetrical prepreg are formed by lamination.

Furthermore, the aforementioned carrier films are selected from a group consisting of metal foil and resin film.

Examples of the aforementioned metal foil include metal foil such as copper foil or aluminum foil, and copper thin film formed by carrying out copper plating treatment on a support.

Examples of the aforementioned resin film include release paper in the manner of polyolefins such as polyethylene or polypropylene, polyesters such as polyethylene terephthalate or polybutylene terephthalate, polycarbonates and silicon sheets, and thermoplastic resin films having heat resistance such as fluororesin or polyimide resin. Among these, a film composed of polyester is most preferable. As a result, the resin film can be easily peeled from the resin layer with suitable force.

An example of a method used to laminate the first and second carrier materials 2′ and 3′ on the fibrous base material 1′ consists of using a vacuum laminator. In this method, after having superimposed the first carrier material from the first side of the fibrous base material 1′, superimposing the second carrier material from the second side, and joining and sealing the carrier layers with laminating rollers under reduced pressure, a resin composition composed of the first and second carrier materials is heat-treated at a temperature equal to or higher than the melting temperature thereof in a hot air drying apparatus. At this time, since the carrier materials are held under reduced pressure as described above, the fibrous base material can be impregnated with the molten carrier materials by capillary phenomenon.

Examples of other heat treatment methods include methods that can be carried out using an infrared heating apparatus, hot roller apparatus or flat hot platen press.

Examples of other methods for obtaining the asymmetrical prepreg are indicated below.

(1) A varnish of a first resin composition serving as the first resin layer 2 is impregnated on one side of the fibrous base material 1′ and dried, the carrier film 2′(film) is superimposed thereon, a varnish of the second resin composition serving as the second resin layer 3 is impregnated on the other side of the fibrous base material 1′ and dried, and the carrier film 3′ (film) is superimposed thereon followed by heating and pressing.

(2) A varnish of the first resin composition is coated, onto the first side of the fibrous base material 1′, impregnated therein and dried to form the first resin layer 2, a varnish of the second resin composition is coated onto the second side of the aforementioned fibrous base material 1′ with a roll coater or comma coater and the like and dried to form the second resin layer 3, and first and second resin layers are advanced to stage B, and the carrier films 2′ (film) and 3′ (film) are respectively superimposed on the surfaces of the stage B first and second resin layers 2 and 3 followed by heating and pressing.

(3) A varnish of the first resin composition is coated onto the fibrous base material 1′, impregnated therein and dried to form the first resin layer 2, and the carrier film 2′ (film) is superimposed on the surface of the aforementioned first resin layer. Moreover, the second carrier material 3′ obtained by coating a varnish of the second resin composition onto the carrier film 3′ (film) is separately produced, and the second resin layer 3′ (layer) is superimposed so as to face the side opposite from the side of the fibrous base material 1′ provided with the first resin layer 2, followed by heating and pressing.

(4) A varnish of the first resin composition is coated onto one side of the fibrous base material 1′ with a die coater and a varnish of the second resin composition is coated onto the other side with a die coater, impregnated therein and dried to respectively form the first resin layer 2 and the second resin layer 3. At this time, the fibrous base material 1′ may be impregnated with the first resin composition or the second resin composition in advance, and a varnish of the first resin composition and a varnish of the second resin composition may be coated with a die coater on one side and the other side, respectively, followed by drying.

(Symmetrical Prepreg)

On the other hand, since the symmetrical prepreg differs from the asymmetrical prepreg in that the thickness of the resin layers on both sides are equal, ordinary impregnation methods can be employed, such as impregnating glass cloth with varnish, coating using various types of coaters, or spraying with a sprayer, and a symmetrical prepreg in stage B can be obtained by impregnating a base material with a resin composition using a suitable method, and drying for 1 to 10 minutes at a temperature of 90° C. to 220° C., for example.

In addition, a symmetrical prepreg can also be obtained by adjusting the thicknesses of the resin layers provided on both sides of the fibrous base material layer so as to be mutually equal using a method similar to the aforementioned asymmetrical prepreg production method.

Examples of methods used to obtain the aforementioned laminate using a prepreg include: (a) a method comprising the use of an asymmetrical prepreg, (b) a method comprising further laminating a resin layer on one side of a symmetrical prepreg, and (c) a method comprising combining prepregs of different thicknesses and laminating.

The following provides a detailed explanation of each of the aforementioned methods of (a) to (c). Furthermore, the thickness of each fibrous base material layer and each resin layer possessed by a laminate prior to heated pressure molding normally does not change that much after heated pressure molding. Consequently, in the aforementioned laminate as well, fibrous base material layers moving in order from a first side are defined as Cx (where, x is an integer represented by 1−n, and n represents the number of fibrous base material layers), the dividing location that results when equally dividing the total thickness (B3) of the laminate by the number (n) of fibrous base material layers and further equally dividing the thickness (B4) of each divided region by two is defined as the reference position of the fibrous base material layer (Cx), and each of the aforementioned reference positions moving in order from the first side is defined as Ax (where, x is an integer represented by 1−n, and n represents the number of fibrous base material layers).

(a) Method Comprising Use of Asymmetrical Prepreg

As was previously described, the asymmetrical prepreg has resin layers on both sides of a fibrous base material layer, and the fibrous base material layer is shifted in the direction of thickness of the prepreg. Thus, a single asymmetrical prepreg can be used as a laminate for obtaining an insulating substrate. An insulating substrate as shown in FIG. 1 can be obtained by subjecting a single asymmetrical prepreg to heated pressure molding followed by curing.

In addition, the aforementioned laminate can also be obtained by combining an asymmetrical prepreg and a symmetrical prepreg and laminating.

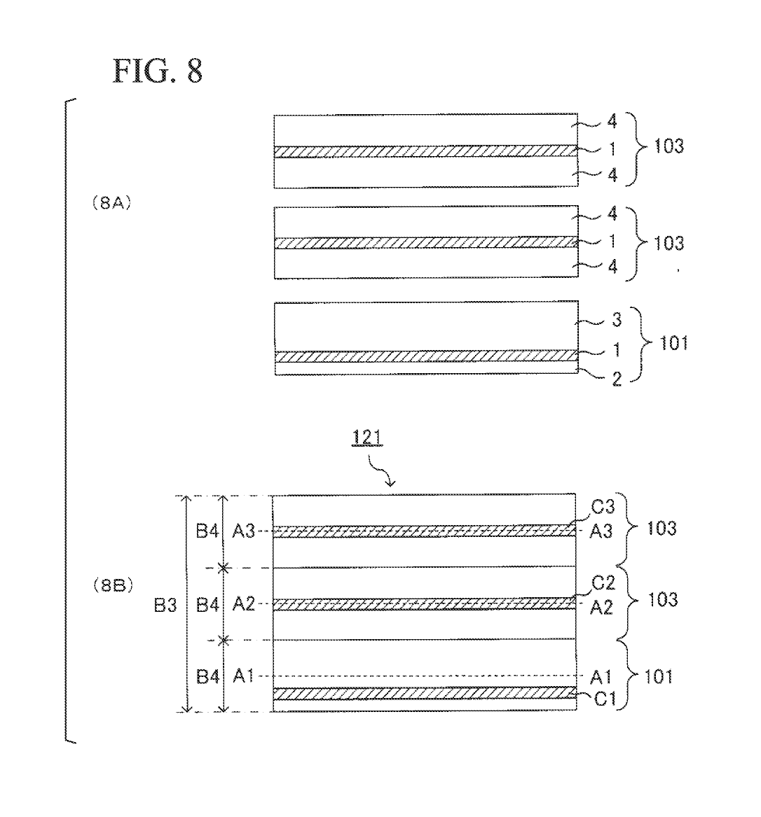

For example, one asymmetrical prepreg 101 and two symmetrical prepregs 103 are first prepared as shown in FIG. 8A. The asymmetrical prepreg 101 has a first resin layer 2 (thin resin layer) on a first side of the fibrous base material layer 1 and a second resin layer 3 (thick resin layer) on a second side, while the symmetrical prepregs 103 have resin layers 4 of the same thickness on both sides of the fibrous base material layer 1. These prepregs have the symmetrical prepreg 101 and the symmetrical prepregs 103 arranged in order starting from the first side, and the asymmetrical prepreg 101 is oriented such that the thin first resin layer 2 is the outermost layer of the first side. Next, as shown in FIG. 8B, these prepregs are superimposed and laminated to obtain a laminate 121. The fibrous base material layer C1 possessed by the laminate 121 is shifted in the direction of the first side from the reference position baseline A1-A1 of the corresponding order. An insulating substrate as shown in FIG. 5A can be obtained by subjecting the resulting laminate 121 to heated pressure molding followed by curing.

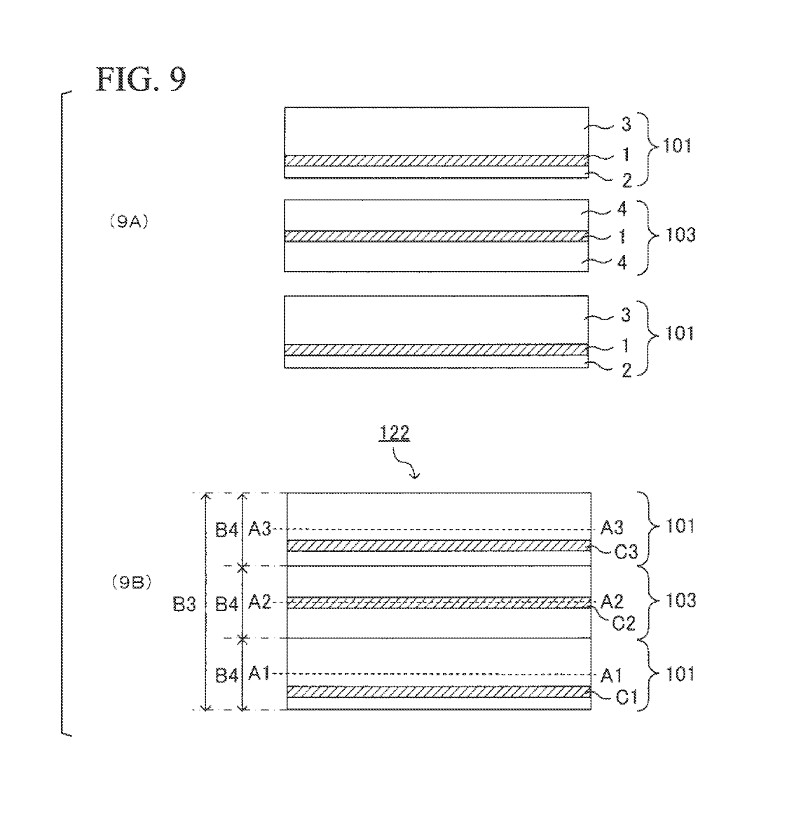

As an example of another method, the asymmetrical prepreg 101, the symmetrical prepreg 103 and the asymmetrical prepreg 101 are first arranged in order starting from the first side as shown in FIG. 9A. Next, as shown in FIG. 9B, these prepregs are superimposed and laminated to obtain a laminate 122.

The aforementioned two asymmetrical prepregs 101 are oriented such that the fibrous base material layers C1 and C3 possessed by the laminate 122 are respectively shifted towards the first side with respect to the reference position baselines A1-A1 and A3-A3 of the corresponding order. An insulating substrate as shown in FIG. 6A can be obtained by subjecting the laminate 122 to heated pressure molding followed by curing.

In addition, although not shown in the drawings, a laminate used in the present invention can also be obtained by laminating a plurality of asymmetrical prepregs.

When using a plurality of asymmetrical prepregs, the asymmetrical prepregs are laminated so that the fibrous base material layers of the asymmetrical prepregs are shifted in the same direction.

Although there are no particular limitations thereon, the thicknesses of the prepregs used in the method of (a) can be suitably adjusted so that at least one of the fibrous base material layers of the resulting laminate is shifted towards the first side or second side with respect to a reference position of the corresponding order, and there are no fibrous base material layers that are shifted in different directions.

(b) Method Comprising Further Laminating Resin Layer on One Side of Symmetrical Prepreg

A method comprising further laminating a resin layer on one side of a symmetrical prepreg is another example of a method for obtaining a laminate used in the present invention. Although there are no particular limitations thereon, examples of methods used to laminate a resin layer on one side of a symmetrical prepreg include a method comprising coating a varnish of the previously described curable resin composition followed by drying, and a method comprising superimposing resin sheets followed by heating and pressing. The aforementioned resin sheet is a sheet contains a resin layer in which the aforementioned curable resin composition in at stage B. A resin sheet obtained by laminating a carrier film on one side or both sides of a resin layer in stage B can also be used for the aforementioned resin sheet. In the case of using such a resin sheet having a carrier film, when laminating on a symmetrical prepreg, the resin sheet is laminated after removing the carrier film on the side that contacts the resin layer of the aforementioned symmetrical prepreg.

A carrier film similar to the carrier film used to fabricate the aforementioned asymmetrical prepreg can be used for the carrier film possessed by the resin sheet. In addition, a resin layer having a resin sheet is composed of the aforementioned curable resin composition in stage B.

Furthermore, according to the definition of JIS-K6900, a sheet refers typically refers to a thin flat sheet in which the ratio of the thickness to the length and width thereof is small, while a film refers to a thin flat product in which the thickness thereof is extremely small in comparison with the length and width and the maximum thickness is arbitrarily limited, and is usually provided in the form of a roll. Thus, although a sheet having an exceptionally small thickness can be said to be a film, since the distinction between a sheet and film is not clear and they are difficult to distinguish definitively, in the present invention, sheets and films are defined as “sheets”, and refer to both those having a large thickness and those having a small thickness.

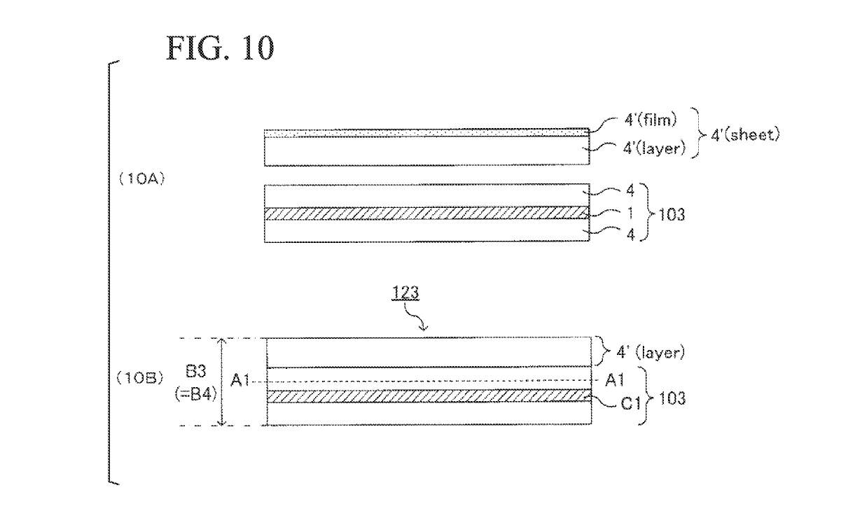

FIG. 10 shows a method for obtaining a laminate used in the present invention by using a symmetrical prepreg and a resin sheet. First, as shown in FIG. 10A, the symmetrical prepreg 103 and a resin sheet 4′ (sheet) composed of a carrier film 4′ (film) and a stage B resin layer 4′ (layer) are prepared, and the resin layer 4′ (layer) of the resin sheet 4′ (sheet) is arranged on a resin layer 4 on one side of the symmetrical prepreg 103 so as to face towards the side of the resin sheet 4 of the symmetrical prepreg 103. Next, the symmetrical prepreg 103 and the resin sheet 4′ (sheet) are superimposed and laminated followed by removal of a carrier film 4′ (film) to obtain a laminate 123 as shown in FIG. 10B. The resin sheet 4′ (sheet) and the symmetrical prepreg 103 are oriented so that the fibrous base material layer C1 possessed by the laminate 123 is shifted towards the first side with respect to the reference position baseline A1-A1. An insulating substrate as shown in FIG. 2A can be obtained by curing the resulting laminate 123.

In addition, a laminate used in the present invention can be obtained by fabricating a plurality of laminates obtained by further laminating a resin layer on one side of the symmetrical prepreg, and superimposing and laminating a plurality of the fabricated laminates. At this time, the aforementioned plurality of laminates is laminated so that there are no fibrous base material layers shifted in different directions.

Although there are no particular limitations thereon, the thicknesses of the prepreg and resin sheet used in the method of (b) can be suitably adjusted so that at least one of the fibrous base material layers of the resulting laminate is shifted towards the first side or second side with respect to a reference position of the corresponding order, and there are no fibrous base material layers that are shifted in different directions.

(c) Method Comprising Combining and Laminating Prepregs of Different Thicknesses

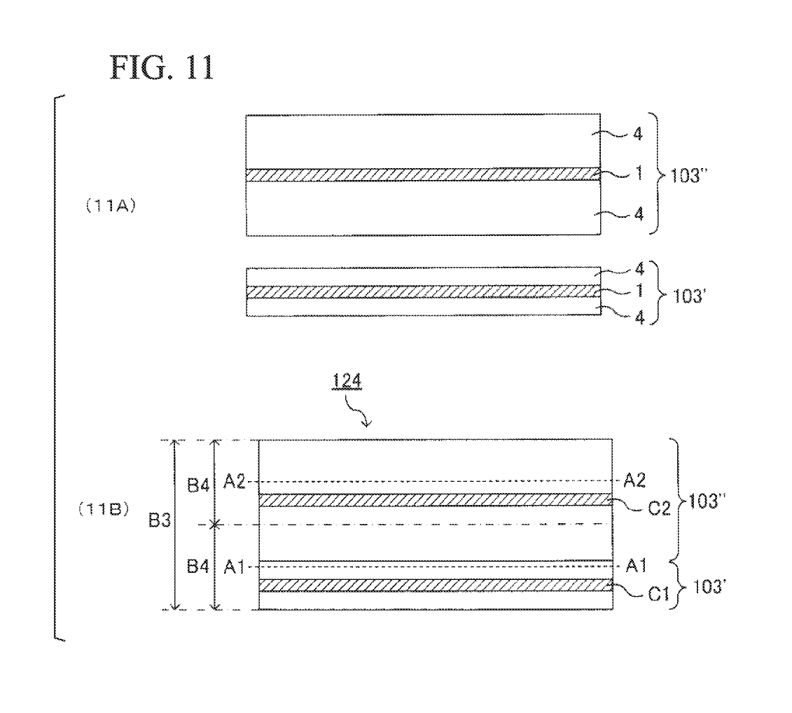

A laminate used in the present invention can also be obtained by combining and laminating prepregs having different thicknesses. For example, a method for combining and laminating symmetrical prepregs of different thicknesses is shown in FIG. 11. First, as shown in FIG. 11A, a comparatively thin symmetrical prepreg 103′ and a comparatively thick symmetrical prepreg 103″ are prepared, and the thin symmetrical prepreg 103′ and the thick symmetrical prepreg 103″ are arranged in order starting from the first side. A laminate 124 shown in FIG. 11B can be obtained by superimposing and laminating these symmetrical prepregs 103′ and 103′. The thin symmetrical prepreg 103′ and the thick symmetrical prepreg 103′ are oriented so that the fibrous base material layers C1 and C2 possessed by the resulting laminate 124 are respectively shifted on the first side from the reference position baselines A1-A1 and A2-A2 of the corresponding order. Furthermore, one fibrous base material layer each is present in each region of thickness B4 in the laminate 124.

The prepregs used in the method of (c) may be any prepregs provided at least one of the fibrous base material layers of the resulting laminate is shifted towards the first side or second side with respect to a reference position of the corresponding order, and there are no fibrous base material layers shifted in different directions. For example, the prepregs are not limited to asymmetrical prepregs as shown in FIG. 11, but rather asymmetrical prepregs can also be used, and the thicknesses thereof can be suitably adjusted without there being any particular limitations thereon.

In addition, a laminate used in the present invention can also be obtained by a method that combines two or more methods selected from the group consisting of the aforementioned methods of (a) to (c). An example thereof consists of respectively fabricating laminates using two or more methods selected from the group consisting of the aforementioned methods of (a) to (c), and then further superimposing and laminating the resulting laminates.

In addition, a laminate used in the present invention may also be a laminate obtained by further laminating a fibrous base material layer and resin layer on a laminate obtained according to the aforementioned methods. An example of a method used to further laminate a fibrous base material and resin layer consists of impregnating one side of a fibrous base material with a varnish of a resin composition followed by drying, laminating a carrier film thereon, and superimposing on one side or both sides of a laminate so that the fibrous base material side is arranged so as to face the resin layer side of the laminate, followed by laminating while heating and pressing. Moreover, the carrier film on the outermost layer of the laminate can be removed and this process can then be repeated. Furthermore, in the case of fabricating a laminate used in the present invention by this method, the thickness of further laminated resin layer is suitably adjusted so that at least one fibrous base material layer possessed by the aforementioned laminate is shifted towards the first side or second side with respect to a reference position of the corresponding order, and there are no fibrous base material layers shifted in different directions.

When fabricating the aforementioned laminate, in the case of using a plurality of prepregs, prepregs obtained by using curable resin compositions and/or fibrous base material layers of different thicknesses can be combined for use as the aforementioned prepregs. In addition, in the case of further laminating resin layers or fibrous base material layers, those having respectively different thicknesses may also be used in combination.

In the aforementioned laminate, in the case a plurality of resin layers are arranged adjacent to each other, mutually adjacent resin layers may be composed of mutually different curable resin compositions within a range that does not affect adhesion between the resin layers.

Furthermore, the aforementioned laminate fabrication method is not limited to that described above, but rather other methods can also be employed provided they are methods that allow the fabrication of a laminate able to be used in the insulating substrate of the present invention.

The insulating substrate of the present invention is normally obtained by subjecting the aforementioned laminate to heated pressure molding at 120° C. to 230° C. and 1 MPa to 5 MPa.

2. Metal-Clad Laminate

The metal-clad laminate of the present invention is characterized by providing a metal foil layer on at least one side of the aforementioned insulating substrate of the present invention.

The metal-clad laminate of the present invention is obtained by, for example, further laminating a metal foil on the outermost resin layer on at least one side of the aforementioned laminate used to produce the insulating substrate of the present invention, and normally subjecting to heated pressure molding at 120° C. to 230° C. and 1 MPa to 5 MPa.

Furthermore, in the case a carrier film other than a metal foil is laminated on the outermost layer of the aforementioned laminate, the metal foil can be laminated on the exposed resin layer by removing the aforementioned carrier film. On the other hand, in the case of using a laminate in which a metal foil is laminated as a carrier film on the outermost layer on at least one side, the metal-clad laminate of the present invention can be obtained by subjecting to heated pressure molding with the aforementioned metal foil still laminated without removing.

Examples of metal foil used in the metal-clad laminate of the present invention include metal foil made of copper, copper alloy, aluminum, aluminum alloy, silver, silver alloy, gold, gold alloy, zinc, zinc alloy, nickel, nickel alloy, tin, tin alloy, iron and iron alloy.

3. Printed Wiring Board

The printed wiring board of the present invention is provided with one or more layers of a conductor circuit layer on at least one side of the aforementioned insulating substrate of the present invention.

A printed wiring board is obtained by using the aforementioned insulating substrate or metal-clad laminate as a core substrate, forming a conductor circuit on one side or both sides thereof by a known method such as a subtractive method, additive method or semi-additive method, and electrically connecting both sides. Normally, a multilayer printed wiring board is obtained by building up interlayer insulating layers and conductor circuit layers on an inner layer circuit formed in the core substrate, electrically connecting the conductor circuit layers, exposing only the terminal portions of the circuit of the outermost layer, and coating the terminal portions with solder resist.

A sheet or prepreg of a heat-curable resin composition can be used for the built-up interlayer insulating layer. A semi-additive method is preferably used to form the conductor circuit layer on the interlayer insulating layer. Electrical connections between both sides of the core substrate or between each of the conductor circuit layers can be made by forming holes with a drill or laser and then forming electrical connections by plating the holes or filling with an electrically conductive material.

In general, printed wiring boards prior to being mounted with a semiconductor element have the potential for the occurrence of positive warping or negative warping due to the effects of the ratio of residual metal (residual area) contained in the conductor circuit layers provided on surface where the semiconductor element is mounted and the circuit pattern thereof, and the ratio of residual metal contained in the conductor circuit layers provided on the opposite side where a semiconductor element is not mounted and the circuit pattern thereof, and what is more, positive warping or negative warping can occur irregularly between individual products even if they use printed wiring boards having the same specifications.

In contrast, in the present invention, an insulating substrate serving as the insulating portion of the core substrate contains one or more fibrous base material layers and two or more resin layers, the outermost layers on both sides are composed of cured products of resin layers in the form of laminates, at least one of the fibrous base material layers is shifted towards a first side or a second side with respect to a reference position of the corresponding order, and there are no fibrous base material layers that are shifted in different directions. As a result, the aforementioned insulating substrate and a printed wiring board that uses the insulating substrate are able to control the direction and degree of warping by being formed either warped outward in the direction in which the fibrous base material layer is shifted or formed flat.

4. Semiconductor Device

The semiconductor device of the present invention is obtained by mounting a semiconductor element on a conductor circuit layer of the aforementioned printed wiring board of the present invention.

In general, since the thermal shrinkage of printed wiring boards is greater than the thermal shrinkage of semiconductor elements, when a semiconductor element is mounted on a surface of a printed wiring board, the side containing the semiconductor element warps outward, resulting susceptibility to the occurrence of so-called negative warping.

In addition, the printed wiring board of the present invention has the property of warping outward in the direction in which a fibrous base material layer contained in a core layer is shifted.

Thus, from the viewpoint of reducing or preventing negative warping of a semiconductor device, the semiconductor device of the present invention preferably has a semiconductor element mounted on a conductor circuit layer provided on a second side on the opposite side from a first side in the direction in which a fibrous base material layer is shifted in an insulating substrate contained in the aforementioned printed wiring board.

From the same viewpoint, among fibrous base material layers possessed by an insulating substrate contained in the aforementioned printing wiring board, the fibrous base material layer closest to the first side is particularly preferably arranged shifted towards the first side with respect to a reference position of the corresponding order, and the aforementioned semiconductor element is particularly preferably mounted on a conductor circuit layer provided on the second side opposite from the first side in the direction in which the fibrous base material layer is shifted.

An example of a method used to mount a semiconductor element on a conductor circuit layer of a printed wiring board consists of forming a die attach layer on a conductor circuit layer on the mounting side of a printed wiring board, temporarily attaching a semiconductor element through the aforementioned die attach layer, and heat-softening or heat-curing the die attach layer while gently pressing as necessary to fix the semiconductor element in position.

A die attach film composed of a thermoplastic resin composition containing a thermoplastic resin such as a (meth)acrylic acid ester copolymer or a die attach paste composed of a heat-curable resin composition containing a heat-curable resin such as epoxy resin, is used for the die attach material.

Normally, the semiconductor element and the printed wiring board are electrically connected by a known method such as the use of a solder ball or wire bonding either simultaneous to or after the semiconductor element has been fixed in position.

Following electrical connection, the element-mounted surface may be sealed by a known method as necessary. Although there are no particular limitations thereon, a conventionally known epoxy resin composition for semiconductor sealing is preferably used for the sealing material. Epoxy resin compositions for semiconductor sealing contain an epoxy resin, curing agent, inorganic filler, curing accelerator, and as necessary, other additives such as a colorant, mold release agent, low stress component or antioxidant, a material obtained by mixing these materials and molding into the form of granules, a sheet or a film can be used as a sealing material, and such a material can be prepared with reference to the description of, for example, Japanese Unexamined Patent Application, First Publication No. 2008-303367.

In addition, an example of another method consists of mounting a semiconductor element having a solder bump on a printed wiring board, and connecting the aforementioned printed wiring board and the semiconductor element through the solder bump. A liquid sealing resin (underfill resin) is then filled between the printed wiring board and the semiconductor element to produce a semiconductor device.

The solder bump is preferably composed of tin, lead, silver, copper, bismuth or an alloy thereof. The method used to connect the semiconductor element and the printed wiring board consists of aligning a connecting electrode portion on the printed wiring board with the solder bump of the semiconductor element using a flip-chip bonder and the like, followed by heating the solder bump to a temperature equal to or higher than the melting point thereof using an IR reflow apparatus, hot plate or other heating apparatus, and connecting the printed wiring board and the semiconductor pump by melting and fusing. Furthermore, in order to improve connection reliability, a layer of a metal having a comparatively low melting point such as solder paste may be preliminarily formed on the connecting electrode portion of the printed wiring board. Connection reliability can also be improved by coating flux onto the solder bump and/or the surface layer of the connecting electrode portion of the printed wiring board prior to this bonding step.

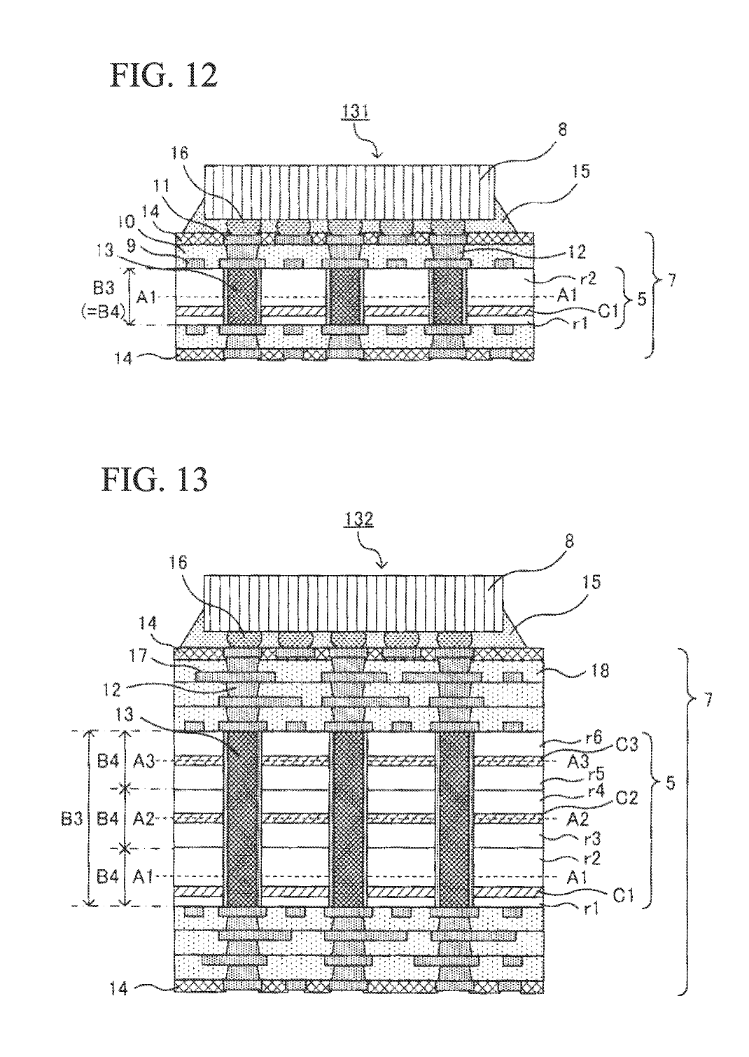

FIG. 12 is a drawing schematically showing a cross-section of an example of mounting a semiconductor element on a printed wiring board having the insulating substrate 111 shown in FIG. 1 as a core layer.

In FIG. 12, a semiconductor device 131 is obtained by mounting a semiconductor element 8 on the opposite side from the side in the direction in which the fibrous base material layer C1 contained in a printed wiring board 7 is shifted.

The printed wiring board 7 of the semiconductor device 131 is provided with multilayered conductor circuit layers on both sides of a core layer 5 of the semiconductor device 131. The core layer 5 of the semiconductor device 131 has the same layer composition as the insulating substrate 111 shown in FIG. 1, and is obtained by laminating the resin layer r1, the fibrous base material layer C1 and the resin layer r2 in order starting from a first side, and the fibrous base material layer C1 is oriented so as to be shifted towards the resin layer r1 with respect to the reference position baseline A1-A1 of the corresponding order.

The portions of the conductor circuit layers are obtained by building up an inner layer circuit 9, interlayer insulating layer 10 and outer layer circuit 11 in that order on both sides of the printed wiring board 7, the inner layer circuit 9 and the outer layer circuit 10 are electrically connected through via holes 12, circuits on both sides of the core substrate are electrically connected by through holes 13, and the outer layer circuits 11 on both sides are coated with a solder resist 14 except for each of the terminal portions.

The semiconductor element 8 is attached through a liquid sealing resin 15 to the opposite side from the side in the direction in which the fibrous base material layer C1 contained in the printed wiring board 7 is shifted, and a terminal portion of the outer layer circuit 11 of the printed wiring board 7 is aligned with an electrode pad provided on the lower surface of the semiconductor element 8, and then connected through a solder bump 16. Furthermore, the element-mounting surface is not sealed in this example.

Since thermal shrinkage of the printed wiring board 7 is greater than thermal shrinkage of the semiconductor element 8, the semiconductor device 131 is susceptible to the occurrence of so-called negative warping. In contrast, since the printed wiring board 7 used in the semiconductor device 131 has the insulating substrate 111 shown in FIG. 1 for the core layer 5 thereof, and the side in the direction in which the fibrous base material layer C1 is shifted has the property of warping outward, the relationship with the side on which the semiconductor element is mounted is such that force is generated that results in so-called positive warping.

Thus, negative warping when the printed wiring board 7 is mounted with a semiconductor element can be reduced, and superior flatness can be imparted to the semiconductor device 131.

FIG. 13 is a drawing schematically showing a cross-section of an example of mounting a semiconductor element on a printed wiring board having the insulating substrate 115 shown in FIG. 5 as a core layer thereof.

In FIG. 13, a semiconductor device 132 is obtained by mounting the semiconductor element 8 on the opposite side from the side in the direction in which the fibrous base material layer C1 contained in the printed wiring board 7 is shifted.

The printed wiring board 7 of the semiconductor device 132 is provided with multilayered conductor circuit layers 17 on both sides of the core layer 5. The core layer 5 of the semiconductor device 132 has the same layer composition as the insulating substrate 115 shown in FIG. 5, and is obtained by laminating the resin layer r1, the fibrous base material layer C1, the resin layers r2 and r3, the fibrous base material layer C2, the resin layers r4 and r5, the fibrous base material layer C3 and the resin layer r6 in order starting from the first side, and the fibrous base material layer C1 of the three fibrous base material layers provided on the outside of the first side is oriented so as to be shifted towards the resin layer r1 with respect to the reference position baseline A1-A1 of the corresponding order, while the fibrous base material layers C2 and C3 are respectively oriented so as to be present at the reference position of the corresponding order.

The portions of the conductor circuit layers 17 are obtained by building up the conductor circuit layers 17 and interlayer insulating layers 18 on both sides of the printed wiring board 7, each conductor circuit layer 17 is electrically connected through the via holes 12, circuits on both sides of the core substrate are electrically connected by the through holes 13, and the outer layer circuits on both sides are coated with the solder resist 14 except for each of the terminal portions.

The semiconductor element 8 is attached through the liquid sealing resin 15 to the opposite side from the side in the direction in which the fibrous base material layer C1 contained in the printed wiring board 7 is shifted, and a terminal portion of the outer layer circuit of the printed wiring board is aligned with an electrode pad provided on the lower surface of the semiconductor element 8, and then connected through the solder bump 16.

Since the printed wiring board 7 used in the semiconductor device 132 has the insulating substrate 115 shown in FIG. 5 for the core layer 5 thereof, and the side of the core layer 5 in the direction in which the fibrous base material layer C1 is shifted as the property of warping outward, the relationship with the side on which the semiconductor element is mounted is such that force is generated that results in so-called positive warping.

Thus, negative warping when the printed wiring board 7 is mounted with a semiconductor element can be reduced, and superior flatness can be imparted to the semiconductor device 132.

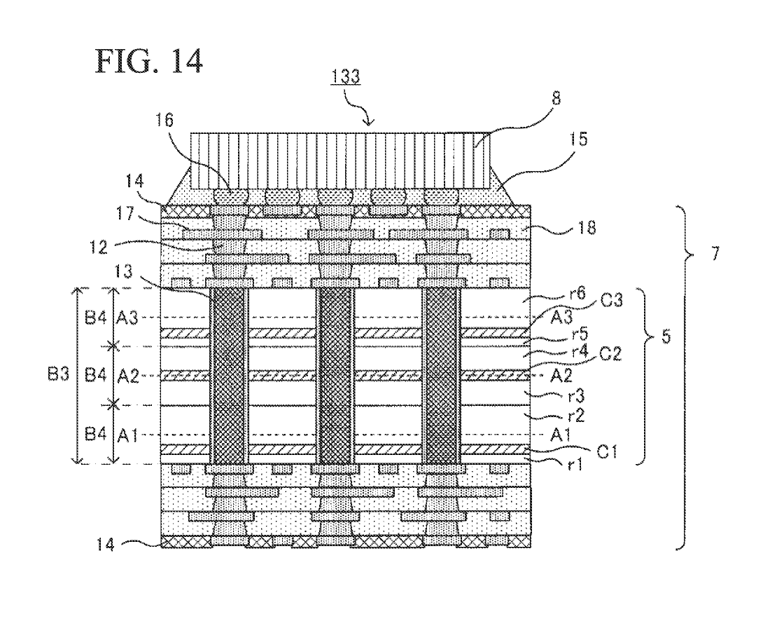

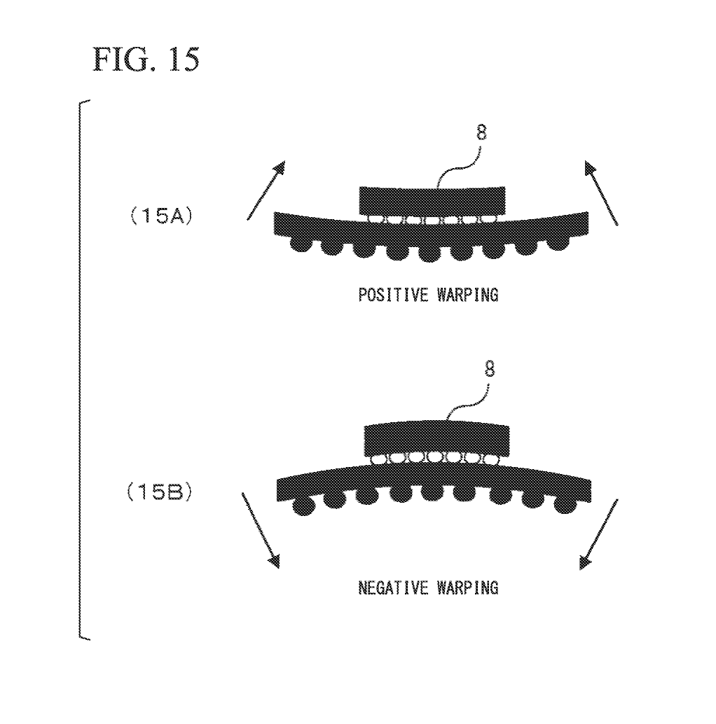

FIG. 14 is a drawing schematically showing a cross-section of an example of mounting a semiconductor element on a printed wiring board having the insulating substrate 116 shown in FIG. 6 as a core layer thereof.

In FIG. 14, a semiconductor device 133 is obtained by mounting the semiconductor element 8 on the opposite side from the side in the direction in which the fibrous base material layers C1 and C3 contained in the printed wiring board 7 are shifted.

The printed wiring board 7 of the semiconductor device 133 is provided with multilayered conductor circuit layers on both sides of the core layer 5. The core layer 5 of the semiconductor device 133 has the same layer composition as the insulating substrate 116 shown in FIG. 6, and is obtained by laminating the resin layer r1, the fibrous base material layer C1, the resin layers r2 and r3, the fibrous base material layer C2, the resin layers r4 and r5, the fibrous base material layer C3 and the resin layer r6 in order starting from the first side. The fibrous base material layer C1 of the three fibrous base material layers provided on the outside of the first side is oriented so as to be shifted towards the resin layer r1 with respect to the reference position baseline A1-A1 of the corresponding order, and the fibrous base material layer C3 provided on the outside of a second side is oriented so as to be shifted towards the resin layer r5 with respect to the reference position baseline A3-A3 of the corresponding order, or in other words, the fibrous base material layers C1 and C3 are shifted in the same direction. The fibrous base material layer C2 is present on the reference position baseline A2-A2 of the corresponding order.

The portions of the conductor circuit layers are obtained by building up in the same manner as the aforementioned semiconductor device 132, and semiconductor element 8 is mounted on the opposite side from the side in the direction in which the fibrous base material layers C1 and C3 contained in the printed wiring board 7 are shifted.

Since the printed wiring board 7 used in the semiconductor device 133 has the insulating substrate 116 shown in FIG. 6 for the core layer 5 thereof, and the side in the direction in which the fibrous base material layers C1 and C3 are shifted has the property of warping outward, the relationship with the side on which the semiconductor element is mounted is such that force is generated that results in so-called positive warping.

Thus, negative warping when the printed wiring board 7 is mounted with a semiconductor element can be reduced, and superior flatness can be imparted to the semiconductor device 133.

In the present invention, by mounting a semiconductor element on the side on the opposite side from the side in the direction in which a fibrous base material layer contained in the core layer (insulating substrate portion) of a printed wiring board is shifted, the printed wiring board prior to being mounted with the semiconductor element is intentionally controlled to demonstrate positive warping or be flat.

As a result, negative warping when a semiconductor element is mounted on the aforementioned printed wiring board can be reduced or completely prevented, and in cases in which warping can be controlled particularly favorably, a flat semiconductor device is obtained that is completely free of both positive warping and negative warping.

Since semiconductor devices having superior flatness demonstrate high positioning accuracy when secondarily connected to a motherboard, defective connections can be prevented and connection reliability can be improved.

In addition, the present invention offers a high degree of design freedom since there are no restrictions on circuit design with respect to the number of conductor circuit layers, circuit patterns and the like as a result of controlling warping of a semiconductor device.

Although warping of a semiconductor device occurs particularly easily when the thickness of the core substrate is reduced in order to accommodate the reduced thickness of semiconductor devices, according to the present invention, a semiconductor device having superior flatness can be obtained in cases of a thin core substrate. In addition, this effect can be demonstrated even in the case of so-called double-sided boards consisting only of a core substrate that do not use an interlayer insulating resin layer.

The present invention is also preferably applied to production processes consisting of mounting a plurality of semiconductor elements on a multi-board printed wiring board.

Here, a multi-board printed wiring board refers to that in which a plurality of printed wiring boards have been integrally formed so as to be continuous in the planar direction. Semiconductor devices can be produced in large volume by mounting a plurality of semiconductor elements on such a multi-board printed wiring board, followed by collectively sealing the sides where the semiconductor elements are mounted, and cutting into individual pieces by dicing and the like.

Since the multi-board printed wiring boards have a large surface area, when a large number of semiconductor elements are mounted thereon in a two-dimensional arrangement, there is considerable generation of negative warping, thereby making it difficult to accurately cut into individual pieces by dicing and the like.

As a result of using the insulating substrate or metal-clad laminate of the present invention for the core substrate of such a multi-board printed wiring board, negative warping of the multi-board printed wiring board can be reduced or completely prevented, and a collectively sealed substrate is obtained that has superior flatness.

### EXAMPLES

Although the following provides a more detailed explanation of the present invention by indicating examples thereof, the present invention is not limited thereto.

First, an explanation is provided of the production of prepregs. The thicknesses of each layer of the resulting prepregs are shown in Table 1. Furthermore, the descriptions of P1 to P11 contained in Tables 1 to 3 refer to Prepreg 1 to Prepreg 11, and the term Unitika contained in Table 1 refers to Unitika Glass Fiber Co., Ltd.

(Prepreg 1)

1. Preparation of Varnish of Heat-Curable Resin Composition

11.0 parts by weight of an epoxy resin in the form of biphenyl aralkyl novolac epoxy resin (Nippon Kayaku Co., Ltd., NC-3000), 8.8 parts by weight of a curing agent in the form of biphenyl dimethylene phenol resin (Nippon Kayaku Co., Ltd., GPH-103) and 20.0 parts by weight of novolac cyanate resin (Lonza Japan Ltd., Primaset PT-30) were dissolved and dispersed in methyl ethyl ketone. Moreover, 60.0 parts by weight of inorganic filler in the form of spherical fused silica (Admatechs Co., Ltd., SO-25R, mean particle diameter: 0.5 μm) and 0.2 parts by weight of a coupling agent (Nippon Unicar Co., Ltd., A187) were added, followed by stirring for 30 minutes using a high-speed stirrer and adjusting to a non-volatile content of 50% by weight to prepare a varnish of a heat-curable resin composition (resin varnish).

2. Production of Carrier Material

The aforementioned resin varnish was coated onto a PET film (polyethylene terephthalate film, Teijin Dupont Films Japan Ltd., Purex Film, thickness: 36 μm) using a die coater to a thickness of the resin layer after drying of 10.0 μm, followed by drying for 5 minutes in a drying apparatus at 160° C. to obtain a resin sheet with PET film for use as a first resin layer.

In addition, the aforementioned resin varnish was similarly coated onto a PET film so that the thickness of the resin layer after drying was 16.0 μm, followed by drying for 5 minutes in a drying apparatus at 160° C. to obtain a resin sheet with PET film for use as a second resin layer.

3. Prepreg Production

The aforementioned resin sheet with PET film for use as a first resin layer and the aforementioned resin sheet with PET film for use as a second resin layer were arranged on both sides of a glass fibrous base material (thickness: 28 μm, Nitto Boseki Co., Ltd., E Glass Woven Fabric, WEA 1035-53-X133, IPC standard 1035) so that the resin layers were facing the fibrous base material, followed by heating and pressing with a vacuum press for 1 minute under conditions of a pressure of 0.5 MPa and temperature of 140° C. to impregnate with the heat-curable resin composition and obtain a Prepreg 1 having a carrier film laminated thereon. The Prepreg 1 was an asymmetrical prepreg having a total thickness of 40 μm in which the thickness of the first resin layer is 3 μm, the thickness of the fibrous base material layer is 28 μm, and the thickness of the second resin layer is 9 μm.

(Prepregs 2 to 6)

Prepregs 2 to 6 were produced in the same manner as Prepreg 1 with the exception of changing the thickness of the first resin layer, the thickness of the second resin layer and the fibrous base material used as shown in Table 1. Furthermore, Prepregs 2 to 6 are asymmetrical prepregs.

(Prepreg 7)

A glass fibrous base material (thickness: 28 μm, Nitto Boseki Co., Ltd., E Glass Woven Fabric, WEA 1035-53-X133, IPC standard 1035) was impregnated with the resin varnish obtained in the manner described above followed by drying for 2 minutes in a heating oven at 150° C. to obtain a Prepreg 7. The Prepreg 7 was a symmetrical prepreg having a total thickness of 40 in which the thickness of the fibrous base material layer is 28 μm and resin layers of the same thickness (6 μm) are provided on both sides of the aforementioned fibrous base material layer.

(Prepregs 8 to 11)

Prepregs 8 to 11 were produced in the same manner as Prepreg 7 with the exception of changing the thicknesses of the resin layers and the fibrous base material used as shown in Table 1. Furthermore, the Prepregs 8 to 11 are symmetrical prepregs.

TABLE 1

| | | Resin sheet with | | | | | Prepreg | | | | |
|---|---|---|---|---|---|---|---|---|---|---|---|
| | | PET film | | | | | Fibrous | | | | |
| | | | Second | | | | base | First | Second | | |
| | | First | resin | Fibrous base material | | | material | resin | resin | Resin | Total |
| | | resin | layer | Trade | IPC | Manu- | layer | layer | layer | layer | thickness |
| | | layer | (μm) | name | style | facturer | (μm) | (μm) | (μm) | (μm) | (μm) |
| Asym- | P1 | 10 | 16 | WEA1035- | #1035 | Nittobo | 28 | 3 | 9 | — | 40 |
| metrical | | | | 53-X133 | | | | | | | |
| | P2 | 15 | 22 | E06C 04 | #1280 | Unitika | 46 | 4 | 10 | — | 60 |
| | | | | 53SK | | | | | | | |
| | P3 | 25 | 35 | E09B 04 | #2319 | Unitika | 80 | 5 | 15 | — | 100 |
| | | | | 53SK | | | | | | | |
| | P4 | 33 | 35 | E15R 04 | #1504 | Unitika | 130 | 1 | 2.3 | — | 133.3 |
| | | | | 53TT | | | | | | | |
| | P5 | 23 | 37 | E09B 04 | #2319 | Unitika | 80 | 3 | 17 | — | 100 |
| | | | | 53SK | | | | | | | |
| | P6 | 29 | 31 | E09B 04 | #2319 | Unitika | 80 | 9 | 11 | — | 100 |
| | | | | 53SK | | | | | | | |
| Sym- | P7 | — | — | WEA1035- | #1035 | Nittobo | 28 | — | — | 6 | 40 |
| metrical | | | | 53-X133 | | | | | | | |
| | P8 | — | — | E06C 04 | #1280 | Unitika | 46 | — | — | 7 | 60 |
| | | | | 53SK | | | | | | | |
| | P9 | — | — | E09B 04 | #2319 | Unitika | 80 | — | — | 10 | 100 |
| | | | | 53SK | | | | | | | |
| | P10 | — | — | E15R 04 | #1504 | Unitika | 130 | — | — | 1.7 | 133.4 |
| | | | | 53TT | | | | | | | |
| | P11 | — | — | E09B 04 | #2319 | Unitika | 80 | — | — | 3 | 86 |
| | | | | 53SK | | | | | | | |

In the following Examples 1 to 8 and Comparative Examples 1 to 4, core substrates (metal-clad laminates) were produced using the aforementioned Prepregs 1 to 11 (simply indicated as P1 to P11 in the table), and printed wiring boards and semiconductor devices were produced using the aforementioned core substrates. Furthermore, the thicknesses of each layer possessed by a core layer to be subsequently described were measured by cutting out a cross-section of each metal-clad laminate and observing the cross-sections with a light microscope.

### Example 1

### 1. Production of Metal-Clad Laminate

A 12 μm copper foil (Mitsui Mining and Smelting Co., Ltd., 3EC-VLP Foil) was superimposed on both sides of Prepreg 1 followed by subjecting to heated pressure molding for 2 hours at 220° C. and 3 MPa to obtain a metal-clad laminate. The core layer (portion composed of an insulating substrate) of the resulting metal-clad laminate had the same layer composition as that of the insulating substrate 111 of FIG. 1A, had a layer composition obtained by laminating in order starting from a first side the resin layer r1, the fibrous base material layer C1 and the resin layer r2, the thicknesses of each layer were 3 μm for r1, 28 μm for C1 and 9 μm for r2, and the aforementioned core layer was such that the fibrous base material layer C1 was shifted towards the resin layer r1 with respect to a reference position. In addition, the total thickness (B3) of the core layer was 40 μm.

The ratio of B5/B6 of the aforementioned core layer was 0.33 since the thickness (B5) of a resin filled region on the first side when based on the fibrous base material layer C1 is the thickness of r1, and the thickness (B6) of a resin filled region on a second side is the thickness of r2.

In addition, since the aforementioned core layer contains only one fibrous base material layer, the thickness of B4 obtained by equally dividing the total thickness (B3) by the number of fibrous base material layers is the same as B3. Accordingly, in the region B4 to which the fibrous base material layer C1 belongs, the distance (B7) from C1 to the first side is the same as the aforementioned B5, while the distance (B8) from C1 to the second side is the same as the aforementioned B6. Thus, the ratio of B7/B8 is also 0.33 in the same manner as the ratio of B5/B6.

2. Production of Printed Wiring Board

A commercially available prepreg (Sumitomo Bakelite Co., Ltd., 6785GS-F, thickness: 50 μm) was superimposed on the front and back of an inner layer circuit board obtained by using the resulting metal-clad laminate as a core substrate and forming a circuit pattern on both sides thereof (residual copper ratio: 70%, L/S=50/50 μm), followed by further superimposing a 12 μm copper foil on the top and bottom thereof and subjecting to heated pressure molding for 2 hours at a pressure of 3 MPa and temperature of 220° C.

Next, the copper foil was removed by etching and blind via holes (non-through holes) were formed with a carbon dioxide laser. Next, the insides of the via holes and the resin layer surface were immersed for 5 minutes in a swelling conditioner (Atotech Japan, K.K., Swelling Dip Securigant P) at 60° C. followed by immersing for 10 minutes in aqueous potassium permanganate solution (Atotech Japan, K.K., Concentrate Compact CP) at 80° C., and then neutralizing and carrying out roughening treatment.

After then going through degreasing, catalyst addition and activation steps, an electroless plate copper film was formed at a thickness of about 0.5 μm, a plating resist was formed, and pattern electroplated copper was formed to a thickness of 10 μm using an electroless copper plated film for the power supply layer, followed by carrying out microcircuit processing at L/S=50/50 μm. Next, after annealing for 60 minutes at 200° C. with a hot air dryer, the power supply layer was removed by flash etching to produce a four-layer printed circuit board.

Next, a solder resist (Taiyo Ink Mfg. Co., Ltd., PSR-4000 AUS703) was printed and exposed with a prescribed mask to expose the semiconductor mounting pad and the like, followed by developing and curing to form a solder resist layer on the circuit having a thickness of 12 μm.

Finally, a plated layer composed of an electroless nickel plated layer of 3 μm and an electroless gold plated layer of 0.1 μm thereon was formed on the circuit layer exposed through the solder resist layer, and the resulting substrate was cut to a size of 14 mm×14 mm to obtain a printed wiring board for a semiconductor device.

3. Production of Semiconductor Device

A semiconductor device was obtained by mounting a semiconductor element having a solder bump (TEG chip, size: 8 mm×8 mm, thickness: 725 μm) on the aforementioned printed wiring board for a semiconductor device by thermocompression bonding using a flip-chip bonder so that the side on the opposite side from the side in the direction in which the fibrous base material layer of the core substrate is shifted is the side where the semiconductor element is mounted, followed by melting and bonding the solder bump in an IR reflow oven, filling with a liquid sealing resin (Sumitomo Bakelite Co., Ltd., CRP-4160A3) and curing the aforementioned liquid sealing resin. Furthermore, the liquid sealing resin was cured under conditions of a temperature of 150° C. for 120 minutes. A solder bump formed with a eutectic Sn/P composition was used for the solder bump of the aforementioned semiconductor element.

### Examples 2 to 5

Printed wiring boards and semiconductor devices of Examples 2 to 5 were produced in the same manner as Example 1 with the exception of respectively producing metal-clad laminates using Prepreg 2 in Example 2, Prepreg 3 in Example 3, Prepreg 5 in Example 4 and Prepreg 6 in Example 5, and using the resulting metal-clad laminates as core substrates. In the core substrates of Examples 2 to 5, the fibrous base material layers were shifted towards the first side with respect to a reference position. Furthermore, semiconductor elements were mounted on printed wiring boards for a semiconductor device so that the side on the opposite side from the side in the direction in which the fibrous base material layer of the core substrate is shifted is the side where the semiconductor element is mounted.

### Example 6

### 1. Production of Metal-Clad Laminate

A total of three prepregs were laminated in the order of Prepreg 10, Prepreg 10 and Prepreg 4 so that the second resin layer of Prepreg 4 was on the side of Prepreg 10 and the first resin layer was on the side of an air layer, 12 μm copper foil (Mitsui Mining and Smelting Co., Ltd., 3EC-VLP Foil) was superimposed on both sides of the resulting laminate followed by subjecting to heated pressure molding for 2 hours at 220° C. and 3 MPa to obtain a metal-clad laminate. The core layer (portion composed of an insulating substrate) of the resulting metal-clad laminate had the same layer composition as that of the insulating substrate 115 of FIG. 5A, and had a layer composition obtained by laminating in order starting from a first side the resin layer r1, the fibrous base material layer C1, the resin layers r2 and r3, the fibrous base material layer C2, the resin layers r4 and r5, the fibrous base material layer C3 and the resin layer r6. The thicknesses of each layer were 130 μm for C1 to C3, 1.0 μm for r1, a total thickness of 4.0 μm for r2 and r3, a total thickness of 3.4 μm for r4 and r5, and a thickness of 1.7 μm for r6. The aforementioned core layer was such that the fibrous base material layer C1 was shifted towards the resin layer r1 with respect to a reference position, and the fibrous base material layers C2 and C3 are present at reference positions of the corresponding order. In addition, the total thickness (B3) of the core layer was 400 μm.

The ratio of B5/B6 of the aforementioned core layer when based on the fibrous base material layer C1 was 0.25 since the thickness (B5) of a resin filled region on the first side when based on the fibrous base material layer C1 is the thickness of r1, and the thickness (B6) of a resin filled region on a second side is the total thickness of r2 and r3.

In addition, since the aforementioned core layer has three fibrous base material layers, the thickness (B4) of each region when the aforementioned total thickness (B3) is equally divided by the number of fibrous base material layers is 133.3 μm, and one fibrous base material layer each was present in each region of the aforementioned thickness B4. In the region of thickness B4 to which the fibrous base material layer C1 belongs, since the distance (B7) from C1 to the first side is the thickness of the resin layer r1, and the distance (B8) from C1 to the second side is the thickness obtained by subtracting the thickness of the resin layer r1 (1.0 μm) and the thickness of the fibrous base material layer C1 (130 μm) from the thickness B4 (133.3 μm), namely 2.3 μm, the ratio of B7/B8 when based on the fibrous base material layer C1 was 0.43.

2. Production of Printed Wiring Board

A commercially available resin sheet with PET film (Ajinomoto Fine-Techno Co., Inc., ABF-GX-13, thickness: 40 μm) was superimposed on the front and back of an inner layer circuit board obtained by using the resulting metal-clad laminate as a core substrate and forming a circuit pattern on both sides thereof (residual copper ratio: 70%, L/S=50/50 μm), followed by subjecting to vacuum heated pressure molding for 120 seconds at a temperature of 150° C. and pressure of 1 MPa using a vacuum press laminator, thereafter heat-curing for 60 minutes at 200° C. with a hot air dryer, peeling off the PET film, and then forming blind via holes (non-through holes) with a carbon dioxide laser. Next, the insides of the via holes and the resin layer surface were immersed for 5 minutes in a swelling conditioner (Atotech Japan, K.K., Swelling Dip Securigant P) at 60° C. followed by immersing for 10 minutes in aqueous potassium permanganate solution (Atotech Japan, K.K., Concentrate Compact CP) at 80° C., and then neutralizing and carrying out roughening treatment.

After then going through degreasing, catalyst addition and activation steps, an electroless plate copper film was formed at a thickness of about 0.5 μm, a plating resist was formed, and pattern electroplated copper was formed to a thickness of 10 μm using an electroless copper plated film for the power supply layer, followed by carrying out microcircuit processing at L/S=50/50 μm. Next, after annealing for 60 minutes at 200° C. with a hot air dryer, the power supply layer was removed by flash etching.

Moreover, an eight-layer printed wiring board was produced in which the outermost layer was subjected to circuit processing by repeating the same steps using resin sheets with PET film.

Next, a solder resist (Taiyo Ink Mfg. Co., Ltd., PSR-4000 AUS703) was printed and exposed with a prescribed mask to expose the semiconductor mounting pad and the like, followed by developing and curing to form a solder resist layer on the circuit having a thickness of 12 μm.

Finally, a plated layer composed of an electroless nickel plated layer of 3 μm and an electroless gold plated layer of 0.1 μm thereon was formed on the circuit layer exposed through the solder resist layer, and the resulting substrate was cut to a size of 50 mm×50 mm to obtain a printed wiring board for a semiconductor device.

3. Production of Semiconductor Device

A semiconductor device was produced in the same manner as Example 1 with the exception of using the printed wiring board for a semiconductor device obtained in the manner described above, and using a TEG chip (size: 15 mm×15 mm, thickness: 725 μm) for the semiconductor element. Furthermore, the semiconductor element was mounted on the printed wiring board for a semiconductor device so that the side on the opposite side from the side in the direction in which the fibrous base material layer C1 contained by the core substrate is shifted is the side where the semiconductor element is mounted.

### Example 7

A printed wiring board and a semiconductor device were obtained in the same manner as Example 6 with the exception of producing a metal-clad laminate by laminating a total of three prepregs in the order of Prepreg 4, Prepreg 10 and Prepreg 4 so that the first resin layer of one of the Prepregs 4 was on the side of the Prepreg 10 while the second resin layer of the other Prepreg 4 was on the side of the Prepreg 10, laminating 12 μm copper foil (Mitsui Mining and Smelting Co., Ltd., 3EC-VLP Foil) on both sides of the resulting laminate, and subjecting to heated pressure molding for 2 hours at 220° C. and 3 MPa, and using the metal-clad laminate obtained thereby as a core substrate. The core layer (portion composed of an insulating substrate) of the resulting metal-clad laminate had the same layer composition as that of the insulating substrate 116 of FIG. 6A, had a layer composition obtained by laminating in order starting from a first side the resin layer r1, the fibrous base material layer C1, the resin layers r2 and r3, the fibrous base material layer C2, the resin layers r4 and r5, the fibrous base material layer C3 and the resin layer r6, and the thicknesses of each layer were 130 μm for C1 to C3, 1.0 μm for r1, a total thickness of 4.0 μm for r2 and r3, a total thickness of 2.7 μm for r4 and r5, and a thickness of 2.3 μm for r6. The aforementioned core layer was such that the fibrous base material layers C1 and C3 were respectively shifted towards the resin layer r1 and the resin layer r5 with respect to reference positions of the corresponding order, and the fibrous base material layer C2 was present at a reference position of the corresponding order. In addition, the total thickness (B3) of the core layer was 400 μm.

The ratio of B5/B6 of the aforementioned core layer when based on the fibrous base material layer C1 was 0.25 since the thickness (B5) of a resin filled region on the first side when based on the fibrous base material layer C1 is the thickness of r1, and the thickness (B6) of a resin filled region on a second side is the total thickness of r2 and r3. In addition, when based on the fibrous base material layer C3, since the thickness (B5) of a resin filled region on the first side is the total thickness of r4 and r5 and the thickness (B6) of a resin filled region on the second side is the thickness of r6, the ratio of B5/B6 when based on the fibrous base material layer C3 was 1.17.

In addition, since the aforementioned core layer has three fibrous base material layers, the thickness (B4) of each region when the aforementioned total thickness (B3) is equally divided by the number of fibrous base material layers is 133.3 μm, and one fibrous base material layer each was present in each region of the aforementioned thickness B4. In the region of thickness B4 to which the fibrous base material layer C1 belongs, since the distance (B7) from C1 to the first side is the thickness of the resin layer r1, and the distance (B8) from C1 to the second side is the thickness obtained by subtracting the thickness of the resin layer r1 (1.0 μm) and the thickness of the fibrous base material layer C1 (130 μm) from the thickness B4 (133.3 μm), namely 2.3 μm, the ratio of B7/B8 when based on the fibrous base material layer C1 was 0.43. In addition, in the region of thickness 34 to which the fibrous base material layer C3 belongs, since the distance (B7) from C3 to the first side is the thickness obtained by subtracting the thickness of the resin layer r6 (2.3 μm) and the thickness of the fibrous base material layer C3 (130 μm) from the thickness B4 (133.3 μm), namely 1.0 μm, and the distance (B8) from C3 to the second side is the thickness of resin layer r6 (2.3 μm), the ratio of B7/B8 when based on the fibrous base material layer C3 was 0.43.

Furthermore, the semiconductor element was mounted on the printed wiring board for a semiconductor device so that the side on the opposite side from the side in the direction in which the fibrous base material layers C1 and C3 contained by the core substrate are shifted is the side where the semiconductor element is mounted.

### Example 8

The resin varnish used with Prepreg 1 was coated onto a PET film (polyethylene terephthalate film, Teijin Dupont Films Japan Ltd., Purex Film, thickness: 36 μm) using a die coater to a thickness of the resin layer after drying of 14.0 μm, followed by drying for 5 minutes in a drying apparatus at 160° C. to obtain a Resin Sheet with PET Film 1.

The resin layer side of the Resin Sheet with PET Film 1 was arranged on Prepreg 11, and the Prepreg 11 and the Resin Sheet with PET Film 1 were laminated from the first side in the order of the Prepreg 11 and the Resin Sheet with PET Film 1. Next, after peeling off the PET film, 12 μm copper foil (Mitsui Mining and Smelting Co., Ltd., 3EC-VLP Foil) was laminated on both sides of the resulting laminate and subjected to heated pressure molding for 2 hours at 220° C. and 3 MPa to produce a metal-clad laminate, and the resulting metal-clad laminate was used as a core substrate. The remainder of the procedure was carried out in the same manner as Example 1 to obtain a printed wiring board and semiconductor device.

The core layer (portion composed of an insulating substrate) of the resulting metal-clad laminate had the same layer composition as that of the insulating substrate 112 of FIG. 2A, and had a layer composition obtained by laminating in order starting from a first side the resin layer r1, the fibrous base material layer C1, and the resin layers r2 and r3. The thicknesses of each layer were 3 μm for r1, 80 μm for C1, and a total thickness of 17 μm for r2 and r3, and the aforementioned core layer was such that the fibrous base material layer C1 was shifted towards the resin layer r1 with respect to a reference position. In addition, the total thickness (B3) of the core layer was 100 μm.

The ratio of B5/B6 of the aforementioned core layer when based on the fibrous base material layer C1 was 0.18 since the thickness (B5) of a resin filled region on the first side when based on the fibrous base material layer C1 is the thickness of r1, and the thickness (B6) of a resin filled region on a second side is the total thickness of r2 and r3.

In addition, since the aforementioned core layer has only one fibrous base material layer, the thickness (B4) when the aforementioned total thickness (B3) is equally divided by the number of fibrous base material layers is the same as B3. Accordingly, in the region B4 to which the fibrous base material layer C1 belongs, the distance (B7) from C1 to the first side is the same as the aforementioned B5, while the distance (B8) from C1 to the second side is the same as the aforementioned B6. Thus, the ratio of B7/B8 was also 0.18 in the same manner as the ratio of B5/B6.

### Comparative Examples 1 to 3

Printed wiring boards and semiconductor devices were produced in Comparative Examples 1 to 3 in the same manner as Example 1 with the exception of respectively producing metal-clad laminates using Prepreg 7 in Comparative Example 1, Prepreg 8 in Comparative Example 2 and Prepreg 9 in Comparative Example 3, and using the resulting metal-clad laminates as core substrates. In the core substrates of Comparative Examples 1 to 3, the fibrous base material layers were present at a reference position.

### Comparative Example 4

A printed wiring board and semiconductor device were produced in Comparative Example 4 in the same manner as Example 6 with the exception of producing a metal-clad laminate using a laminate obtained by laminating three Prepregs 10, and using the resulting metal-clad laminate as a core substrate. In the core substrate used in Comparative Example 4, all of the fibrous base material layers were present at reference positions of the corresponding order.

The semiconductor devices obtained according to each of the examples and comparative examples were subjected to each of the following evaluations. Each evaluation is shown below together with the evaluation method. The evaluation results obtained are shown in Tables 2 and 3. In addition, the amounts of change in package warping ((package warping of comparative examples)−(package warping of examples)) between the examples and comparative examples are shown in Table 4.

(1) Amount of Package (PKG) Warping

Warping of the semiconductor package at normal temperature) (25° was measured for the semiconductor devices fabricated in each of the aforementioned examples and comparative examples using a variable temperature laser, three-dimensional coordinate measuring system (LS200-MT100MT50, Ti-Tec Co., Ltd.). The measuring range was set to a range of 48 mm×48 mm for Examples 6 and 7 and Comparative Example 4 and to range of 13 mm×13 mm for the other semiconductor devices, and measurements were carried out by emitting a laser onto the BGA side on the opposite side from the side where the semiconductor element is mounted, and defining warping to be the difference between the farthest point and the closest point over the distance from the laser head.

(2) Temperature Cycle (TC) Test

The semiconductor devices obtained in each of the aforementioned examples and comparative examples were subjected to 1000 cycles of treatment, with one cycle consisting of holding in air for 15 minutes at −65° C. followed by holding at 150° C. for 15 minutes or holding at 150° C. for 15 minutes followed by holding at −65° C. for 15 minutes, followed by carrying out a continuity test at 100 locations on circuit terminals extending from the printed circuit board, passing through the semiconductor element via the solder bump, and then returning to the printed circuit board using a flying probe checker (1116X-YC Hi-Tester, Hioki Co., Ltd.) to examine for the presence of disconnections at those locations. The meanings of the symbols used in the tables are as indicated below.

⊚: No disconnections

◯: Disconnections at 1 to 10 locations

Δ: Disconnections at 11 to 50 locations

X: Disconnections at 51 locations or more

TABLE 2

| | | | | | | | Ex.8 | | | |
|---|---|---|---|---|---|---|---|---|---|---|
| | | | | | | | P11 + | Comp. | Comp. | Comp. |
| Core layer | | Ex.1 | Ex.2 | Ex.3 | Ex.4 | Ex.5 | resin | Ex.1 | Ex.2 | Ex.3 |
| composition | | P1 | P2 | P3 | P5 | P6 | sheet 1 | P7 | P8 | P9 |
| Layer | r1 | 3 | 4 | 5 | 3 | 9 | 3 | 6 | 7 | 10 |
| thickness | C1 | 28 | 46 | 80 | 80 | 80 | 80 | 28 | 46 | 80 |
| (μm) | r2* | 9 | 10 | 15 | 17 | 11 | 17 | 6 | 7 | 10 |

| | | | | | | | | | |
|---|---|---|---|---|---|---|---|---|---|
| Core layer total | 40 | 60 | 100 | 100 | 100 | 100 | 40 | 60 | 100 |
| thickness (B3) (μm) | | | | | | | | | |
| B5/B6 | 0.33 | 0.40 | 0.33 | 0.18 | 0.82 | 0.18 | — | — | — |
| B7/B8 | 0.33 | 0.40 | 0.33 | 0.18 | 0.82 | 0.18 | | | |
| Substrate size (mm) | 14 × 14 | 14 × 14 | 14 × 14 | 14 × 14 | 14 × 14 | 14 × 14 | 14 × 14 | 14 × 14 | 14 × 14 |
| Chip size (mm) | 8 × 8 | 8 × 8 | 8 × 8 | 8 × 8 | 8 × 8 | 8 × 8 | 8 × 8 | 8 × 8 | 8 × 8 |
| PKG warping (μm) | −179 | −170 | −157 | −155 | −164 | −156 | −201 | −188 | −172 |
| TC test result | ◯ | ◯ | ⊚ | ⊚ | ⊚ | ⊚ | × | × | Δ |

*Total thickness of r2 and r3 for Example 8

TABLE 3

| | | Ex. 6 | Ex. 7 | Comp. Ex. 4 |
|---|---|---|---|---|
| Core layer composition | | P10 + P10 + | P4 + P10 + | P10 + P10 + |
| | | P4 | P4 | P10 |
| Layer | r1 | 1.0 | 1.0 | 1.7 |
| thickness | C1 | 130 | 130 | 130 |
| (μm) | r2 | 4.0 | 4.0 | 3.4 |
| | r3 | | | |
| | C2 | 130 | 130 | 130 |
| | r4 | 3.4 | 2.7 | 3.4 |
| | r5 | | | |
| | C3 | 130 | 130 | 130 |
| | r6 | 1.7 | 2.3 | 1.7 |

| | | | |
|---|---|---|---|
| Core layer total thickness | 400 | 400 | 400 |
| (B3) (μm) | | | |
| B5/B6 | 0.25 | 0.25 | — |
| | (based on C1) | (based on C1) | |
| | | 1.17 | |
| | | (based on C3) | |
| B7/B8 | 0.43 | 0.43 | — |
| | (based on C1) | (based on C1) | |
| | | 0.43 | |
| | | (based on C3) | |
| Substrate size (mm) | 50 × 50 | 50 × 50 | 50 × 50 |
| Chip size (mm) | 15 × 15 | 15 × 15 | 15 × 15 |
| PKG warping (μm) | −187 | −183 | −195 |
| TC test result | ⊚ | ⊚ | Δ |

TABLE 4

| | Ex.1 | Ex.2 | Ex.3 | Ex.4 | Ex.5 | Ex.6 | Ex.7 | Ex.8 |
|---|---|---|---|---|---|---|---|---|
| Change in PKG | −22 | −18 | −15 | −17 | −8 | −8 | −12 | −16 |
| warping (μm) | | | | | | | | |
| (Comp.Ex. (μm)- | | | | | | | | |
| Ex.(μm)) | | | | | | | | |
| Compared to | Comp. | Comp. | Comp. | Comp. | Comp. | Comp. | Comp. | Comp. |
| Comp.Ex. | Ex.1 | Ex.2 | Ex.3 | Ex.3 | Ex.3 | Ex.4 | Ex.4 | Ex.3 |

As shown in Tables 2 and 3, the semiconductor devices obtained in Examples 1 to 8 and Comparative Examples 1 to 4 demonstrated negative warping.

In order to confirm effects in the case of using as a core layer an insulating substrate according to the present invention, namely an insulating substrate in which at least one fibrous base material layer is shifted towards a first side or a second side with respect to a reference position of the corresponding order and in which there are no fibrous base material layers shifted in different directions, a comparison was made between examples and comparative examples having an equal number of fibrous base material layers of the same thickness (same type) and having equal sizes and thicknesses of the core layer, package and chip, for changes in the amount of package warping, the results of which are shown in Table 4. If the thickness and number of fibrous base material layers, thicknesses of the core layer, package and chip, and sizes of the chip differ, the radius of curvature of package warping differs, and as a result thereof, the amount of package warping differs. In addition, if the core layer and package size differ, larger sizes of core layers and packages demonstrate an overall increase in package warping even the radius of curvature of package warping is the same. Consequently, it is necessary to ensure that these parameters are uniform when comparing the examples and comparative examples.

As can be seen from Table 4, the amount of package warping decreased in Examples 1 to 8 as compared with the comparative examples used as controls. As a result, the semiconductor devices of Examples 1 to 8, which were obtained by using a core substrate in which at least one of the fibrous base material layers is shifted towards a first side or second side with respect to a reference position of the corresponding order, and in which there are no fibrous base material layers shifted in different directions, clearly demonstrated reduced package warping as compared with the semiconductors of Comparative Examples 1 to 4, which were obtained by using core substrates in which all of the fibrous base material layers were present at reference positions of the corresponding order.

In addition, as can be seen from Tables 2 and 3, in contrast to the semiconductors of Comparative Examples 1 to 4 demonstrating numerous disconnections in the temperature cycle test resulting in inferior connection reliability, the semiconductors obtained in Examples 1 to 8 demonstrated none or few disconnections in the temperature cycle test, resulting in superior connection reliability.

### INDUSTRIAL APPLICABILITY

According to the present invention, as a result of at least one fibrous base material layer contained by an insulating substrate being shifted towards a first side or a second side with respect to a reference position of the order corresponding to the aforementioned fibrous base material, and there being no fibrous base material layers shifted in different directions, the aforementioned insulating substrate and a printed wiring board using that insulating substrate are formed either warped outward in the direction in which the aforementioned fibrous base material layer is shifted or flat, and the direction and degree of warping can be controlled. Thus, by aligning the direction in which the aforementioned fibrous base material layer contained in the aforementioned insulating substrate or the aforementioned printed wiring board is shifted so as to be towards the opposite side from the side on which a semiconductor element is mounted, a printed wiring board prior to mounting with a semiconductor element is intentionally controlled to a state of positive warping or being flat, and as a result thereof, negative warping of a semiconductor device, in which a semiconductor element is mounted on the aforementioned printed wiring board, is reduced or completely prevented.

In addition, according to the present invention, since there are no restrictions on circuit design, such as the number of conductor circuit layers for controlling warping of a semiconductor or the circuit pattern, there is a high degree of design freedom.

Thus, the present invention can be preferably used in an insulating substrate serving as a core substrate for producing a printed wiring board, a printed wiring board that uses the aforementioned insulating substrate, and a semiconductor device.

### BRIEF DESCRIPTION OF THE REFERENCE SYMBOLS

101 Asymmetrical prepreg
102 Asymmetrical prepreg with carrier films
103,103′,103″ Symmetrical prepreg
111,112,113,114,115,116 Insulating substrate
121,122,123,124 Laminate
131,132,133 Semiconductor device
C1-C3 Fibrous base material layer
r1-r6 Resin layer
1 Fibrous base material layer
2 First resin layer
3 Second resin layer
2′ First carrier material
3′ Second carrier material
4 Resin layer
5 Core layer
7 Printed wiring board
8 Semiconductor element
9 Conductor circuit layer (inner layer circuit)
10 Interlayer insulating layer
11 Conductor circuit layer (outer layer circuit)
12 Via hole
13 Through hole
14 Solder resist
15 Liquid sealing resin
16 Solder bump
17 Conductor circuit layer (inner circuit layer)
18 Interlayer insulating layer

1. An insulating substrate composed of a cured product of a laminate comprising one or more fibrous base material layers and two or more resin layers, in which the outermost layers on both sides is the resin layers, wherein
when the fibrous base material layers contained in the insulating substrate are defined as Cx moving in order from a first side (where, x is an integer represented by 1−n, and n is the number of the fibrous base material layers), and
when a total thickness (B3) of the insulating substrate is equally divided by the number (n) of the fibrous base material layers, and each divided region having the thickness (B4) is further equally divided by two, where the dividing position is defined as a reference position, and each reference position is defined as Ax in order from the first side (where, x is an integer represented by 1−n, and n is the number of the fibrous base material layers),
at least one of the fibrous base material layers (Cx) is shifted towards the first side or a second side on the opposite side thereof with respect to the reference position (Ax) of the corresponding order (x), and the fibrous base material layers (Cx) are not shifted in different directions.

2. The insulating substrate according to claim 1, wherein
at least one of the fibrous base material layers is shifted towards the first side with respect to the reference position of the corresponding order, and
in the shifted fibrous base material layer,
a ratio (B5/B6) of a thickness (B5) of a resin filled region on the first side of the fibrous base material layer to a thickness (B6) of a resin filled region on the second side of the fibrous base material layer is such that 0.1<B5/B6<1.2.

3. The insulating substrate according to claim 2, wherein the number of the fibrous base material layers is 1 or 2.

4. The insulating substrate according to claim 1, wherein one fibrous base material layer each is present in each region of the equally divided thickness (B4).

5. The insulating substrate according to claim 1, wherein at least one of each region of the equally divided thickness (B4) has a single fibrous base material layer shifted towards the first side with respect to the reference position of the corresponding order, and
in the shifted fibrous base material layer,
a ratio (B7/B8) of a distance (B7) from an interface on the first side of the fibrous base material layer to an interface on the first side of a region of thickness (B4) to which the fibrous base material layer belongs, to a distance (B8) from an interface on the second side of the fibrous base material layer to an interface on the second side of a region of thickness (B4) to which the fibrous base material layer belongs, is such that 0.1<B7/B8<0.9.

6. The insulating substrate according to claim 1, wherein the fibrous base material layer as located closest to the first side among the fibrous base material layers possessed by the insulating substrate is arranged to be shifted towards the first side with respect to the reference position of the corresponding order.

7. The insulating substrate according to claim 1, wherein the fibrous base material layer as located closest to the second side among the fibrous base material layers possessed by the insulating substrate is arranged to be shifted towards the first side with respect to the reference position of the corresponding order.

8. The insulating substrate according to any of claim 1, wherein the total thickness is 0.03 mm to 0.5 mm.

9. The insulating substrate according to claim 1 composed of a cured product of a single prepreg or a laminate obtained by superimposing two or more prepregs, wherein
a first resin layer is provided on a first side of a fibrous base material layer and a second resin layer is provided on the other side, and at least one asymmetrical prepreg is contained in which the thickness of the first resin layer is smaller than the thickness of the second resin layer.

10. A metal-clad laminate, comprising a metal foil layer provided on at least one side of the insulating substrate according to claim 1.

11. A printed wiring board, comprising one or two or more conductor circuit layers provided on at least one side of the insulating substrate according to claim 1.

12. A semiconductor device, comprising a semiconductor element mounted on the conductor circuit layer of the printed wiring board according to claim 11.

13. The semiconductor device according to claim 12, wherein a semiconductor element is mounted on the conductor circuit layer provided on a second side being the
opposite side of a first side located toward the direction in which a fibrous base material layer is shifted in the insulating substrate contained in the printed wiring board.

14. The semiconductor device according to claim 12, wherein among the fibrous base material layers possessed by the insulating substrate contained in the printed wiring board, the fibrous base material layer as located closest to the first side is arranged to be shifted towards the first side with respect to the reference position of the corresponding order, and
the semiconductor element is mounted on a conductor circuit layer provided on a second side being the opposite side of the first side located toward the direction in which the fibrous base material is shifted.

15. The insulating substrate according to claim 2, wherein one fibrous base material layer each is present in each region of the equally divided thickness (B4).

16. The insulating substrate according to claim 3, wherein one fibrous base material layer each is present in each region of the equally divided thickness (B4).

17. The insulating substrate according to claim 2, wherein at least one of each region of the equally divided thickness (B4) has a single fibrous base material layer shifted towards the first side with respect to the reference position of the corresponding order, and
in the shifted fibrous base material layer,
a ratio (B7/B8) of a distance (B7) from an interface on the first side of the fibrous base material layer to an interface on the first side of a region of thickness (B4) to which the fibrous base material layer belongs, to a distance (B8) from an interface on the second side of the fibrous base material layer to an interface on the second side of a region of thickness (B4) to which the fibrous base material layer belongs, is such that 0.1<B7/B8<0.9.

18. The insulating substrate according to claim 3, wherein at least one of each region of the equally divided thickness (B4) has a single fibrous base material layer shifted towards the first side with respect to the reference position of the corresponding order, and
in the shifted fibrous base material layer,
a ratio (B7/B8) of a distance (B7) from an interface on the first side of the fibrous base material layer to an interface on the first side of a region of thickness (B4) to which the fibrous base material layer belongs, to a distance (B8) from an interface on the second side of the fibrous base material layer to an interface on the second side of a region of thickness (B4) to which the fibrous base material layer belongs, is such that 0.1<B7/B8<0.9.

19. The insulating substrate according to claim 4, wherein at least one of each region of the equally divided thickness (B4) has a single fibrous base material layer shifted towards the first side with respect to the reference position of the corresponding order, and
in the shifted fibrous base material layer,
a ratio (B7/B8) of a distance (B7) from an interface on the first side of the fibrous base material layer to an interface on the first side of a region of thickness (B4) to which the fibrous base material layer belongs, to a distance (B8) from an interface on the second side of the fibrous base material layer to an interface on the second side of a region of thickness (B4) to which the fibrous base material layer belongs, is such that 0.1<B7/B8<0.9.

20. The insulating substrate according to claim 2, wherein the fibrous base material layer as located closest to the first side among the fibrous base material layers possessed by the insulating substrate is arranged to be shifted towards the first side with respect to the reference position of the corresponding order.
